(19) United States
(12) Patent Application Publication
(10) Pub. No.: US 2026/0149452 A1
(43) Pub. Date: May 28, 2026

(54) ELECTRONIC DEVICE HAVING LOW POWER AND AREA-EFFICIENT LOGIC CELL-BASED SRAM

(71) Applicant: MEDIATEK INC., Hsinchu City (TW)

(72) Inventors: Manish TRIVEDI, Bengaluru KA (IN); Ramesh HALLI, Bengaluru KA (IN); Sriharsha ENJAPURI, Bengaluru KA (IN); Trivikram DOMMETI, Bengaluru KA (IN); Girishankar GURUMURTHY, Bengaluru KA (IN)

(21) Appl. No.: 19/274,886

(22) Filed: Jul. 21, 2025

(30) Foreign Application Priority Data
Nov. 22, 2024 (IN) 202421091121

(51) Int. Cl. H03K 19/17704; H03K 19/0944

(52) U.S. Cl. CPC H03K 19/17704; H03K 19/0944

(57) ABSTRACT

An electronic device includes a logic cell. The logic cell includes a plurality of N-bit cells and a plurality of P-bit cells. The N-bit cells and the P-bit cells are alternately row-wise to constitute one column of the logic cell array. The N-bit cells are disposed on even rows of the logic cell array, and the P-bit cells are disposed on odd rows of the logic cell array.

### CROSS REFERENCE TO RELATED APPLICATIONS

This Application claims the benefit of India Application No. 202421091121, filed on Nov. 22, 2024, the entirety of which is incorporated by reference herein.

### BACKGROUND OF THE INVENTION

### Field of the Invention

The present invention relates to an electronic device, and, in particular, it relates to an electronic device having low power and an area-efficient logic cell-based SRAM.

### Description of the Related Art

In recent years, there has been a reverse technological trend in foundry SRAM bit cells. Unlike logic circuits, wherein each successive generation goes into lower tech nodes, the bit area of foundry SRAM cells is not being scaled down. The large area requirements of standard cell-based elements (such as flop-flops) raises the need for alternative solutions to capitalize on the logic density scaling.

xCPU SRAM uses a segmented bit line technique (multi-bank) for high speed and lower dynamic power by splitting the bit line load into smaller units, for example, 32 rows per bank. However, segmented bit line architecture requires a large amount of area, as with the foundry bit cell array, as it needs separator edge cells (e.g., 10 CPP) between the array, for the IO interface.

The SRAM array design rule checking (DRC) rules must ensure compliance between the SRAM fin boundary and the IO boundary (e.g., 6 CPP), as well as between the SRAM fin boundary and the interface standard cell boundary. Based upon instance size, SRAM spacing rules (for example, edge cell and fin boundary spacing) causes about a 5%-20% area impact.

### BRIEF SUMMARY OF THE INVENTION

An embodiment of the present invention provides an electronic device. The electronic device includes a logic cell. The logic cell includes a plurality of N-bit cells and a plurality of P-bit cells. The N-bit cells and the P-bit cells are alternately row-wise to constitute one column of the logic cell array. The N-bit cells are disposed on even rows of the logic cell array, and the P-bit cells are disposed on odd rows of the logic cell array.

According to the electronic device described above, each N-bit cell includes a first n-type metal-oxide-semiconductor field-effect transistor (N-MOSFET) region and a first p-type metal-oxide-semiconductor field-effect transistor (P-MOSFET) region. Each P-bit cell includes a second N-MOSFET region and a second P-MOSFET region. The contact poly pitch (CPP) of the first N-MOSFET region is greater than the CPP of the second N-MOSFET region. The CPP of the first P-MOSFET region is less than the CPP of the second P-MOSFET region.

According to the electronic device described above, each N-bit cell and its neighboring P-bit cell forms a rectangle (when viewed from the top view of the layout) to maximize area utilization.

The electronic device further includes a first bit line and a second bit line. The first bit line is electrically connected to the N-bit cells in the column of the logic cell array. The second bit line is electrically connected to the P-bit cells in the column of the logic cell array.

According to the electronic device described above, the first bit line is pre-charged to a logic high level at the start of a read operation. The second bit line is pre-discharged to a logic low level at the start of the read operation.

According to the electronic device described above, the first bit line is discharged from the logic high level to the logic low level during a read-zero operation. The first bit line stays at the logic high level during a read-one operation.

According to the electronic device described above, the second bit line stays at the logic low level during the read-zero operation. The second bit line is charged to the logic high level during the read-one operation.

According to the electronic device described above, the read-zero operation is performed when the N-bit cells or the P-bit cells are storing zero. The read-one operation is performed when the N-bit cells or the P-bit cells are storing one.

The electronic device further includes a read sensing circuit. The read sensing circuit is electrically connected to the logic cell array. The read sensing circuit determines outputs from the even rows of the logic cell array or the odd rows of the logic cell array, and converts logic levels on the first bit line and the second bit line during a read-zero operation or a read-one operation.

According to the electronic device described above, each N-bit cell includes a pass transistor, an NMOS stack, a first transistor, a second transistor, a third transistor, a fourth transistor, a fifth transistor, and a sixth transistor. The pass transistor is electrically connected to a word line and is controlled by a first write-word-line control signal and a second write-word-line control signal. The NMOS stack charges or discharges or maintains the first bit line according to a read-word-line control signal. The first transistor has a first end, a second end, and a control end. The first transistor's first end is electrically connected to a first voltage. The first transistor's second end is electrically connected to the NMOS stack. The first transistor's control end is electrically connected to the pass transistor. The second transistor has a first end, a second end, and a control end. The second transistor's first end is electrically connected to the NMOS stack. The second transistor's second end is electrically connected to a ground. The second transistor's control end is electrically connected to the pass transistor. The third transistor has a first end, a second end, and a control end. The third transistor's first end is electrically connected to the first voltage. The third transistor's control end is electrically connected to the first write-word-line control signal. The fourth transistor has a first end, a second end, and a control end. The fourth transistor's first end is electrically connected to the second end of the third transistor. The fourth transistor's second end is electrically connected to the pass transistor. The fourth transistor's control end is electrically connected to the NMOS stack. The fifth transistor had a first end, a second end, and a control end. The fifth transistor's first end is electrically connected to the pass transistor. The fifth transistor's control end is electrically connected to the NMOS stack. The sixth transistor has a first end, a second end, and a control end. The sixth transistor's first end is electrically connected to the second end of the fifth transistor. The sixth transistor's second end is electrically connected to the ground. The sixth transistor's control end is electrically connected to the second write-word-line control signal.

According to the electronic device described above, the NMOS stack includes a seventh transistor and an eighth transistor. The seventh transistor has a first end, a second end, and a control end. The seventh transistor's first end is electrically connected to the second bit line. The seventh transistor's control end is electrically connected to the read-word-line control signal. The eighth transistor has a first end, a second end, and a control end. The eighth transistor's first end is electrically connected to the second end of the seventh transistor. The eighth transistor's is electrically connected to the ground. The eighth transistor's control end is electrically connected to the second end of the first transistor, the control end of the fourth transistor, and the control end of the fifth transistor.

According to the electronic device described above, each P-bit cell includes a pass transistor, a PMOS stack, a first transistor, a second transistor, a third transistor, a fourth transistor, a fifth transistor, and a sixth transistor. The pass transistor is electrically connected to a word line and is controlled by a first write-word-line control signal and a second write-word-line control signal. The PMOS stack charges or discharges or maintains the second bit line according to a read-word-line control signal. The first transistor has a first end, a second end, and a control end. The first transistor's first end is electrically connected to a first voltage. The first transistor's second end is electrically connected to the PMOS stack. The first transistor's control end is electrically connected to the pass transistor. The second transistor has a first end, a second end, and a control end. The second transistor's first end is electrically connected to the PMOS stack. The second transistor's second end is electrically connected to a ground. The second transistor's control end is electrically connected to the pass transistor. The third transistor has a first end, a second end, and a control end. The third transistor's first end is electrically connected to the first voltage. The third transistor's control end is electrically connected to the first write-word-line control signal. The fourth transistor has a first end, a second end, and a control end. The fourth transistor's first end is electrically connected to the second end of the third transistor. The fourth transistor's second end is electrically connected to the pass transistor. The fourth transistor's control end is electrically connected to the PMOS stack. The fifth transistor has a first end, a second end, and a control end. The fifth transistor's first end is electrically connected to the pass transistor. The fifth transistor's control end is electrically connected to the PMOS stack. The sixth transistor has a first end, a second end, and a control end. The sixth transistor's end is electrically connected to the second end of the fifth transistor. The sixth transistor's second end is electrically connected to the ground. The sixth transistor's control end is electrically connected to the second write-word-line control signal.

According to the electronic device described above, the PMOS stack includes a seventh transistor and an eighth transistor. The seventh transistor has a first end, a second end, and a control end. The seventh transistor's first end is electrically connected to the second bit line. The seventh transistor's control end is electrically connected to the read-word-line control signal. The eighth transistor has a first end, a second end, and a control end. The eighth transistor's first end is electrically connected to the second end of the seventh transistor. The eighth transistor's second end is electrically connected to the first voltage. The eighth transistor's control end is electrically connected to the second end of the first transistor, the control end of the fourth transistor, and the control end of the fifth transistor.

According to the electronic device described above, the read sensing circuit includes local input and output (IO) circuit, and a global IO circuit. The local IO circuit is electrically connected to the logic cell array. The local IO circuit converts logic levels on the first bit line based on a first pre-charge signal and converts the logic levels on the second bit line based on a second pre-charge signal during the read-zero operation or the read-one operation. The global IO circuit is electrically connected to the local IO circuit. The global IO circuit determines outputs from the even rows of the logic cell array or the odd rows of the logic cell array based on a first selection signal and a second selection signal.

According to the electronic device described above, the local IO circuit outputs a first global signal to the global IO circuit based on the logic levels on the first bit line, and outputs a second global signal to the global IO circuit based on the logic levels on the second bit line.

According to the electronic device described above, the global IO circuit outputs a read-result signal based on the first and second selection signals, the first global signal, the second global signal, and data stored in the N-bit cells and the P-bit cells.

According to the electronic device described above, the local IO circuit includes a first transistor and a second transistor. The first transistor has a first end, a second end, and a control end. The first transistor's first end is electrically connected to a first voltage. The first transistor's second end is electrically connected to the first bit line. The first transistor's control end is electrically connected to the first pre-charge signal. The second transistor has a first end, a second end, and a control end. The second transistor's first end is electrically connected to the second bit line. The second transistor's second end is electrically connected to a ground. The second transistor's control end is electrically connected to the second pre-charge signal.

The electronic device further includes a second logic cell array. The second logic cell array includes a plurality of N-bit cells and a plurality of P-bit cells. The N-bit cells and the P-bit cells are alternately row-wise to constitute one column of the second logic cell array. The N-bit cells are disposed on even rows of the second logic cell array, and the P-bit cells are disposed on odd rows of the second logic cell array.

According to the electronic device described above, the local IO circuit is electrically connected between the logic cell array and the second logic cell array.

The electronic device further includes a third bit line and a fourth bit line. The third bit line is electrically connected to the N-bit cells in the column of the second logic cell array. The fourth bit line is electrically connected to the P-bit cells in the column of the second logic cell array.

According to the electronic device described above, the local IO circuit further includes a NAND gate, a NOR gate, a first inverter, and a second inverter. The NAND gate is electrically connected to the first bit line and the third bit line. The NAND gate performs a NAND operation on the logic levels of the first bit line and the third bit line to obtain a first result. The NOR gate is electrically connected to the second bit line and the fourth bit line, configured to perform a NOR operation on the logic levels of the second bit line and the fourth bit line to obtain a second result. The first inverter is electrically connected to the NAND gate. The first inverter inverts the first result to output the first global signal. The second inverter is electrically connected to the NOR gate. The second inverter inverts the second result to output the second global signal.

### BRIEF DESCRIPTION OF THE DRAWINGS

The present invention can be more fully understood by reading the subsequent detailed description and examples with references made to the accompanying drawings.

FIG. 1 is a schematic diagram of an electronic device 110 included in an electronic device 110 in accordance with some embodiments of the present invention.

FIG. 2A is a layout diagram of an N-bit cell 104-0 and a P-bit cell 103-0 in FIG. 1 in accordance with some embodiments of the present invention.

FIG. 2B is a layout diagram of a combination of the N-bit cell 104-0 and the P-bit cell 103-0 in FIG. 1 in accordance with some embodiments of the present invention.

FIG. 3A is a circuit diagram of N-bit cells 102-0, . . . , (102+N-1)-0 in FIG. 1 in accordance with some embodiments of the present invention.

FIG. 3B is a timing diagram of internal operations of the N-bit cell 102-0 in FIG. 1 during a read-zero operation (READ-0) in accordance with some embodiments of the present invention.

FIG. 3C is a timing diagram of internal operations of the N-bit cell 102-0 in FIG. 1 during a read-one operation (READ-1) in accordance with some embodiments of the present invention.

FIG. 4A is a circuit diagram of P-bit cells 103-0, . . . , (102+N)-0 in FIG. 1 in accordance with some embodiments of the present invention.

FIG. 4B is a timing diagram of internal operations of the P-bit cell 103-0 in FIG. 1 during the read-zero operation (READ-0) in accordance with some embodiments of the present invention.

FIG. 4C is a timing diagram of internal operations of the P-bit cell 103-0 in FIG. 1 during the read-one operation (READ-1) in accordance with some embodiments of the present invention.

FIG. 5A is a schematic diagram of an electronic device 500 including the logic cell array 100 in FIG. 1 and a read sensing circuit in accordance with some embodiments of the present invention.

FIG. 5B is a timing diagram of control signals for the electronic device 500 to read the N-bit cell 102-0 in FIG. 1 in accordance with some embodiments of the present invention.

FIG. 5C is a timing diagram of control signals for the electronic device 500 to read the P-bit cell 103-0 in FIG. 1 in accordance with some embodiments of the present invention.

FIG. 6A is a circuit diagram of a local input and output (IO) circuit 502 included in the electronic device 500 in FIG. 5A in accordance with some embodiments of the present invention.

FIG. 6B is a circuit diagram of a global IO circuit 504 included in the electronic device 500 in FIG. 5A in accordance with some embodiments of the present invention.

FIG. 7 is a schematic diagram of an electronic device 730 in accordance with some embodiments of the present invention.

FIG. 8 is a schematic diagram of a logic cell array 810 included in an electronic device 800 in accordance with some embodiments of the present invention.

FIG. 9A is a schematic diagram of an electronic device 900 in accordance with some embodiments of the present invention.

FIG. 9B is a circuit diagram of a P-bit cell 940 in a logic cell array 904 in FIG. 9A in accordance with some embodiments of the present invention.

FIG. 9C is a circuit diagram of an N-bit cell 920 in the logic cell array 904 in FIG. 9A in accordance with some embodiments of the present invention.

FIG. 10A is a schematic diagram of an electronic device 1000 in accordance with some embodiments of the present invention.

FIG. 10B is a schematic diagram of an electronic device 1020 in accordance with some embodiments of the present invention.

FIG. 11A is a schematic diagram of an electronic device 1100 in accordance with some embodiments of the present invention.

FIG. 11B is a circuit diagram of a P-bit cell 1150 in a logic cell array 1104 in FIG. 11A in accordance with some embodiments of the present invention.

FIG. 11C is a circuit diagram of an N-bit cell 1120 in the logic cell array 1104 in FIG. 11A in accordance with some embodiments of the present invention.

FIG. 12A is a circuit diagram of a P-bit cell 1250 in an 2R1W logic cell array in accordance with some embodiments of the present invention.

FIG. 12B is a circuit diagram of an N-bit cell 1220 in the 2R1W logic cell array in accordance with some embodiments of the present invention.

### DETAILED DESCRIPTION OF THE INVENTION

In order to make the above purposes, features, and advantages of some embodiments of the present invention more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” or “include” used in the present invention are used to indicate the existence of specific technical features, values, method steps, operations, units or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present invention. Regarding the drawings, the drawings show the general characteristics of methods, structures, or materials used in specific embodiments. However, the drawings should not be construed as defining or limiting the scope or properties encompassed by these embodiments. For example, for clarity, the relative size, thickness, and position of each layer, each area, or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, and “third” are used to describe components. They are not used to indicate the priority order of or advance relationship, but only to distinguish components with the same name.

It should be noted that the technical features in different embodiments described in the following can be replaced, recombined, or mixed with one another to constitute another embodiment without depart in from the spirit of the present invention.

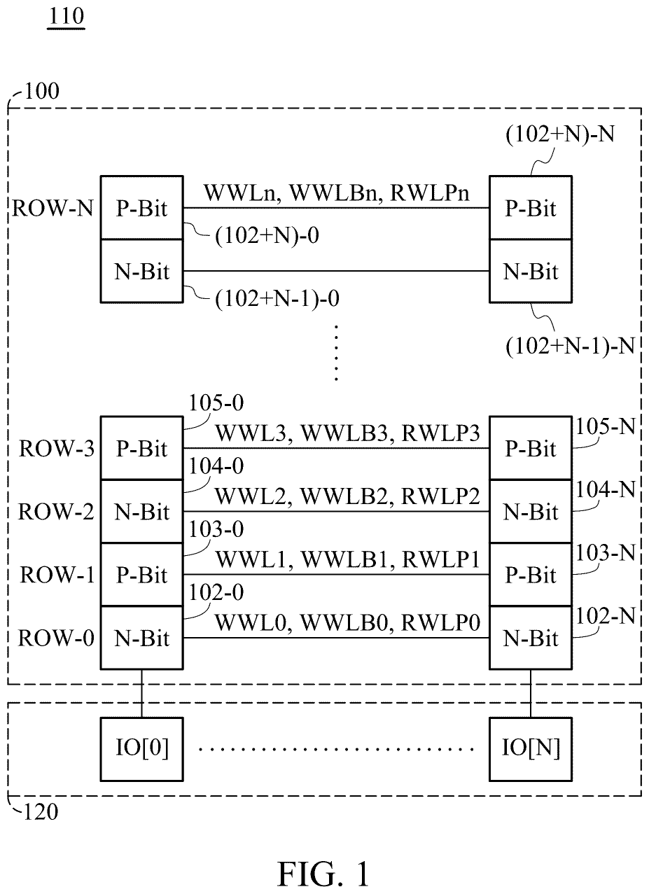

FIG. 1 is a schematic diagram of an electronic device 110 included in an electronic device 110 in accordance with some embodiments of the present invention. As shown in FIG. 1, the electronic device 110 includes a logic cell array 100 and input and output (IO) circuits 120. The logic cell array 100 includes a plurality of N-bit cells and a plurality of P-bit cells. For example, the logic cell array 100 includes N-bit cells 102-0, . . . , 102-N and N-bit cells 104-0, . . . , 104-N. The logic cell array 100 includes P-bit cells 103-0, . . . , 103-N and P-bit cells 105-0, . . . , 105-N. The N-bit cells and the P-bit cells are alternately row-wise to constitute one column of the logic cell array 100. The N-bit cells are disposed on even rows of the logic cell array 100, and the P-bit cells are disposed on odd rows of the logic cell array 100.

For example, FIG. 1 illustrates that the logic cell array 100 has N rows, for example, including a row ROW-0, a row ROW-1, a row ROW-2, a row ROW-3, . . . , ROW-n. The N-bit cells 102-0, . . . , 102-N are disposed in the row ROW-0. The P-bit cells 103-0, . . . , 103-N are disposed in the row ROW-1. The N-bit cells 104-0, . . . , 104-N are disposed in the row ROW-2. The P-bit cells 105-0, . . . , 105-N are disposed in the row ROW-3. Furthermore, some other N N-bit cells in the logic cell array 100 are disposed in the row ROW-(N-1), such as the N-bit cells (102+N-1)-0 and (102+N-1)-N, and some other N P-bit cells in the logic cell array 100 are disposed in the row ROW-N, such as the P-bit cells (102+N)-0 and (102+N)-N.

The N-bit cells 102-0, . . . , 102-N are controlled by write-word-line control signals WWL0 and WWLB0 and a read-word-line control signal RWLP0. The P-bit cells 103-0, . . . , 103-N are controlled by write-word-line control signals WWL1 and WWLB1 and a read-word-line control signal RWLP1. The N-bit cells 104-0, . . . , 104-N are controlled by write-word-line control signals WWL2 and WWLB2 and a read-word-line control signal RWLP2. The P-bit cells 105-0, . . . , 105-N are controlled by write-word-line control signals WWL3 and WWLB3 and a read-word-line control signal RWLP3. The P-bit cells in the row ROW-N are controlled by write-word-line control signals WWLn and WWLBn and a read-word-line control signal RWLPn.

The IO circuits 120 are electrically connected to the logic cell array 100. The IO circuits 120 determines outputs from the even rows of the logic cell array 100 or the odd rows of the logic cell array 100, and converts logic levels on a bit line RBL_QN and a bit line RBL_QP during a read-zero operation or a read-one operation. The IO circuits 120 include IO circuits IO[0], . . . , IO[N]. For example, the IO circuit IO[0] is electrically connected to the N-bit cell 102-0. The IO circuit IO[N] is electrically connected to the N-bit cell 102-N. In some embodiments, the electronic device 110 is a static random-access memory (SRAM), but the present invention is not limited thereto. In some embodiments, the electronic device 110 is a custom logic array (CLA) with single mux (mux-1) architecture.

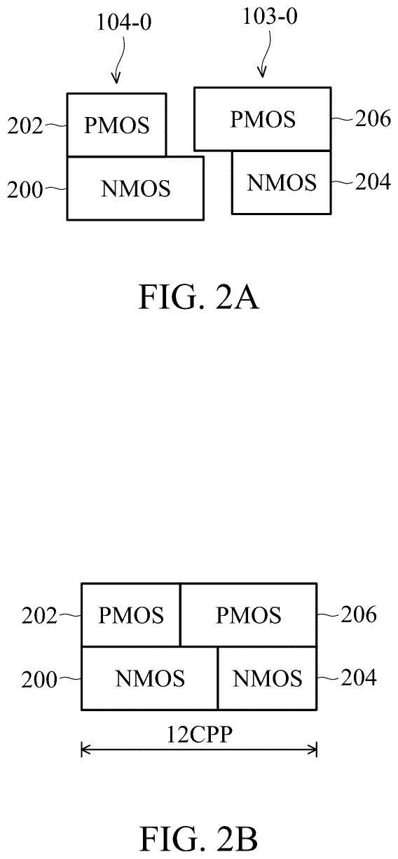

FIG. 2A is a layout diagram of an N-bit cell 104-0 and a P-bit cell 103-0 in FIG. 1 in accordance with some embodiments of the present invention. As shown in FIG. 2A, the N-bit cell 104-0 includes an n-type metal-oxide-semiconductor field-effect transistor (N-MOSFET) region 200 and a p-type metal-oxide-semiconductor field-effect transistor (P-MOSFET) region 202. The P-bit cell 103-0 includes a N-MOSFET region 204 and a P-MOSFET region 206. In some embodiments, the CPP of the N-MOSFET region 200 in the N-bit cell 104-0 is greater than the CPP of the N-MOSFET region 204 in the P-bit cell 103-0. The CPP of the P-MOSFET region 202 in the N-bit cell 104-0 is less than the CPP of the P-MOSFET region 206 in the P-bit cell 103-0.

FIG. 2B is a layout diagram of a combination of the N-bit cell 104-0 and the P-bit cell 103-0 in FIG. 1 in accordance with some embodiments of the present invention. As shown in FIG. 2B, since the CPP of the N-MOSFET region 200 in the N-bit cell 104-0 is greater than the CPP of the N-MOSFET region 204 in the P-bit cell 103-0, and the CPP of the P-MOSFET region 202 in the N-bit cell 104-0 is less than the CPP of the P-MOSFET region 206 in the P-bit cell 103-0, the N-bit cell 104-1 and its neighboring P-bit cell (for example, P-bit cell 103-0) forms a rectangle (when seen from the top view of the layout) to maximize area utilization. In some embodiments, the length of the combination of the N-bit cell 104-0 and the P-bit cell 103-0 may be 12 CPP, but the present invention is not limited thereto.

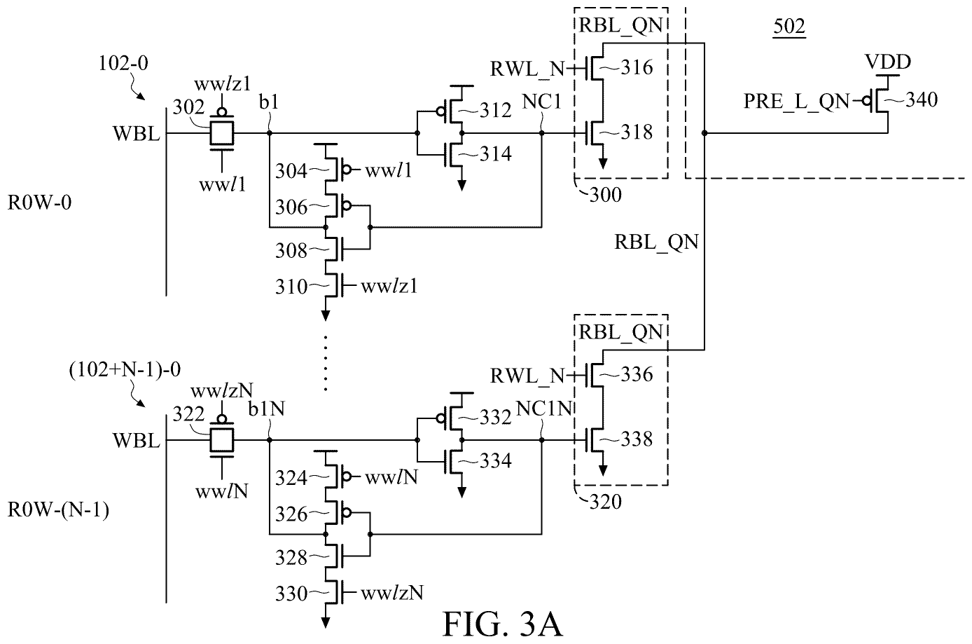

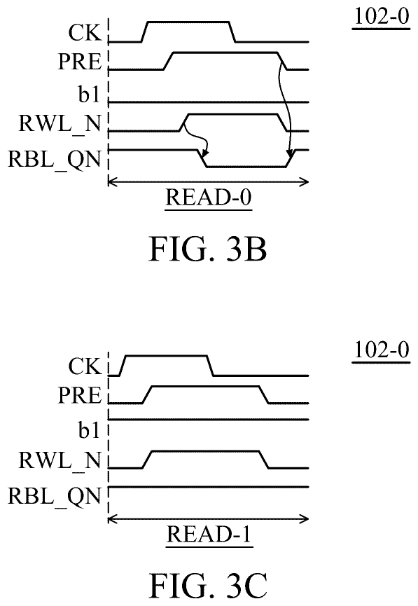

FIG. 3A is a circuit diagram of N-bit cells 102-0, . . . , (102+N-1)-0 in FIG. 1 in accordance with some embodiments of the present invention. As shown in FIG. 3A, the N-bit cell 102-0 includes an NMOS stack 300, a pass transistor 302, a transistor 304, a transistor 306, a transistor 308, a transistor 310, a transistor 312, and a transistor 314. The pass transistor 302 is electrically connected to a word line WBL and is controlled by a write-word-line control signal wwl1 and a write-word-line control signal wwlz1. The NMOS stack 300 charges or discharges or maintains a bit line RBL_QN according to a read-word-line control signal RWL_N. The transistor 312 has a first end, a second end, and a control end. The transistor 312's first end is electrically connected to a voltage VDD. The transistor 312's second end is electrically connected to the NMOS stack 300 through a node NC1. The transistor 312's control end is electrically connected to the pass transistor 302 through a node b1. The transistor 314 has a first end, a second end, and a control end. The transistor 314's first end is electrically connected to the NMOS stack 300 through the node NC1. The transistor 314's second end is electrically connected to a ground. The transistor 314's control end is electrically connected to the pass transistor 302 through the node b1.

The transistor 304 has a first end, a second end, and a control end. The transistor 304's first end is electrically connected to the voltage VDD. The transistor 304's control end is electrically connected to the write-word-line control signal wwl1. The transistor 306 has a first end, a second end, and a control end. The transistor 306's first end is electrically connected to the second end of the transistor 304. The transistor 306's second end is electrically connected to the pass transistor 302 through the node b1. The transistor 306's control end is electrically connected to the NMOS stack 300 through the node NC1. The transistor 308 has a first end, a second end, and a control end. The transistor 308's first end is electrically connected to the pass transistor 302 through the node b1. The transistor 308's control end is electrically connected to the NMOS stack 300 through the node NC1. The transistor 310 has a first end, a second end, and a control end. The transistor 310's first end is electrically connected to the second end of the transistor 308. The transistor 310's second end is electrically connected to the ground. The transistor 310's control end is electrically connected to the write-word-line control signal wwlz1.

In some embodiments, the NMOS stack 300 includes a transistor 316 and a transistor 318. The transistor 316 has a first end, a second end, and a control end. The transistor 316's first end is electrically connected to the bit line RBL-QN. The transistor 316's control end is electrically connected to the read-word-line control signal RWL_N. The transistor 318 has a first end, a second end, and a control end. The transistor 318's first end is electrically connected to the second end of the transistor 316. The transistor 318's second end is electrically connected to the ground. The transistor 318's control end is electrically connected to the second end of the transistor 312, the control end of the transistor 306, and the control end of the transistor 308 through the node NC1. In some embodiments of FIG. 3A, the transistors 312, 304, and 306 are p-type transistors. The transistors 314, 308, 310, 316, and 318 are n-type transistors. The N-bit cells 102-0 and 104-0 are electrically connected to form the bit line RBL-QN[0]. The N-bit cells 102-N and 104-N are electrically connected to form the bit line RBL-QN[N].

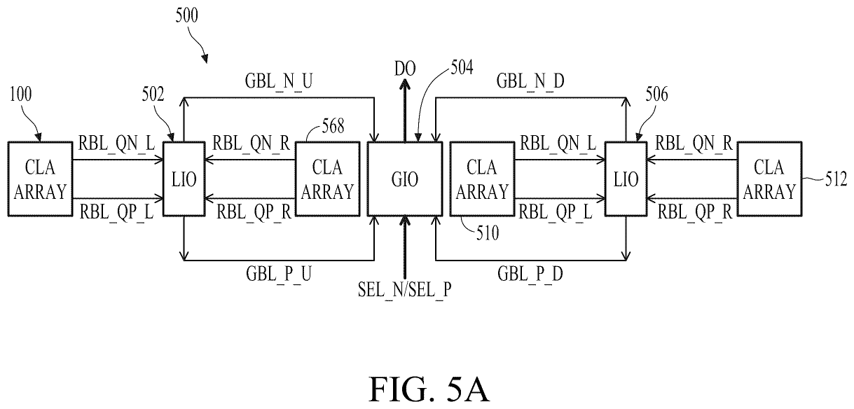

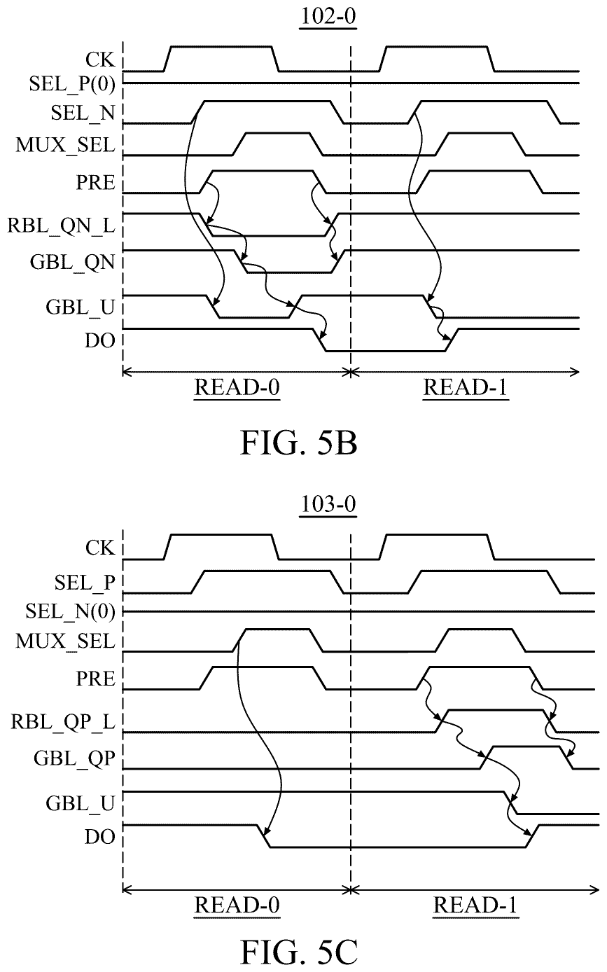

In some embodiments, the bit line RBL-QN is electrically connected to the second end of a transistor 340. The first end of the transistor 340 is electrically connected to the voltage VDD. The transistor 340 is included in an output (IO) circuit (LIO) 502 in FIG. 5.

Similarly, the N-bit cell (102+N-1)-0 includes an NMOS stack 320, a pass transistor 322, a transistor 324, a transistor 326, a transistor 328, a transistor 330, a transistor 332, and a transistor 334. The pass transistor 322 is electrically connected to the word line WBL and is controlled by a write-word-line control signal wwlN and a write-word-line control signal wwlzN. The NMOS stack 320 charges or discharges or maintains a bit line RBL_QN according to the read-word-line control signal RWL_N. The transistor 332 has a first end, a second end, and a control end. The transistor 332's first end is electrically connected to a voltage VDD. The transistor 332's second end is electrically connected to the NMOS stack 320 through a node NC1N. The transistor 332's control end is electrically connected to the pass transistor 322 through a node b1N. The transistor 334 has a first end, a second end, and a control end. The transistor 334's first end is electrically connected to the NMOS stack 320 through the node NC1N. The transistor 334's second end is electrically connected to the ground. The transistor 334's control end is electrically connected to the pass transistor 302 through the node b1N.

The transistor 324 has a first end, a second end, and a control end. The transistor 324's first end is electrically connected to the voltage VDD. The transistor 324's control end is electrically connected to the write-word-line control signal wwlN. The transistor 326 has a first end, a second end, and a control end. The transistor 326's first end is electrically connected to the second end of the transistor 324. The transistor 326's second end is electrically connected to the pass transistor 322 through the node b1N. The transistor 326's control end is electrically connected to the NMOS stack 320 through the node NC1N. The transistor 328 has a first end, a second end, and a control end. The transistor 328's first end is electrically connected to the pass transistor 322 through the node b1N. The transistor 328's control end is electrically connected to the NMOS stack 320 through the node NC1N. The transistor 330 has a first end, a second end, and a control end. The transistor 330's first end is electrically connected to the second end of the transistor 328. The transistor 330's second end is electrically connected to the ground. The transistor 330's control end is electrically connected to the write-word-line control signal wwlzN.

In some embodiments, the NMOS stack 320 includes a transistor 336 and a transistor 338. The transistor 336 has a first end, a second end, and a control end. The transistor 336's first end is electrically connected to the bit line RBL-QN. The transistor 336's control end is electrically connected to the read-word-line control signal RWL_N. The transistor 338 has a first end, a second end, and a control end. The transistor 338's first end is electrically connected to the second end of the transistor 336. The transistor 338's second end is electrically connected to the ground. The transistor 338's control end is electrically connected to the second end of the transistor 332, the control end of the transistor 326, and the control end of the transistor 328 through the node NC1N. In some embodiments of FIG. 3A, the transistors 332, 324, and 326 are p-type transistors. The transistors 334, 328, 330, 336, and 338 are n-type transistors.

In some embodiments, the second end of the transistor 340 included in the LIO 502 is electrically connected to the N-bit cells 102-0, . . . , (102+N-1)-0.

FIG. 3B is a timing diagram of internal operations of the N-bit cell 102-0 in FIG. 1 during a read-zero operation (READ-0) in accordance with some embodiments of the present invention. In some embodiments, the read-zero operation (READ-0) is performed when the N-bit cells or the P-bit cells are storing zero. FIG. 3B illustrates the timing diagram of a clock signal CK, a pre-charge signal PRE, a voltage on the node b1, the read-word-line control signal RWL_N, and a voltage on the bit line RBL_QN during the read-zero operation (READ-0). As shown in FIG. 3B, the clock signal CK rises up from a logic low level to a logic high level first. The pre-charge signal PRE then rises up when the clock signal CK maintains at the logic high level. Next, the read-word-line control signal RWL_N rises up after the pre-charge signal PRE rises up. The bit line RBL_QN is pre-charged to the logic high level at the start of the read-zero operation (READ-0). When the read-word-line control signal RWL_N rises up, the NMOS stack 300 is turned on, causing the voltage on the bit line RBL_QN to pull down at the logic low level. The voltage on the node b1 is always at the logic low level during the read-zero operation (READ-0). The voltage on the bit line RBL_QN is discharged from the logic high level to the logic low level during the read-zero operation (READ-0).

FIG. 3C is a timing diagram of internal operations of the N-bit cell 102-0 in FIG. 1 during a read-one operation (READ-1) in accordance with some embodiments of the present invention. In some embodiments, the read-one operation (READ-1) is performed when the N-bit cells or the P-bit cells are storing one. FIG. 3C illustrates the timing diagram of the clock signal CK, the pre-charge signal PRE, the voltage on the node b1, the read-word-line control signal RWL_N, and the voltage on the bit line RBL_QN during the read-one operation (READ-1). As shown in FIG. 3C, the clock signal CK rises up from the logic low level to the logic high level first. The pre-charge signal PRE then rises up when the clock signal CK maintains at the logic high level. The bit line RBL_QN is pre-charged to the logic high level at the start of the read-one operation (READ-1). When the read-word-line control signal RWL_N rises up, the NMOS stack 300 is turned off, causing the voltage on the bit line RBL_QN to be maintained at the logic high level. The voltage one the node b1 is always at the logic high level during the read-one operation (READ-1). The voltage on the bit line RBL_QN stays at the logic high level during the read-one operation (READ-1).

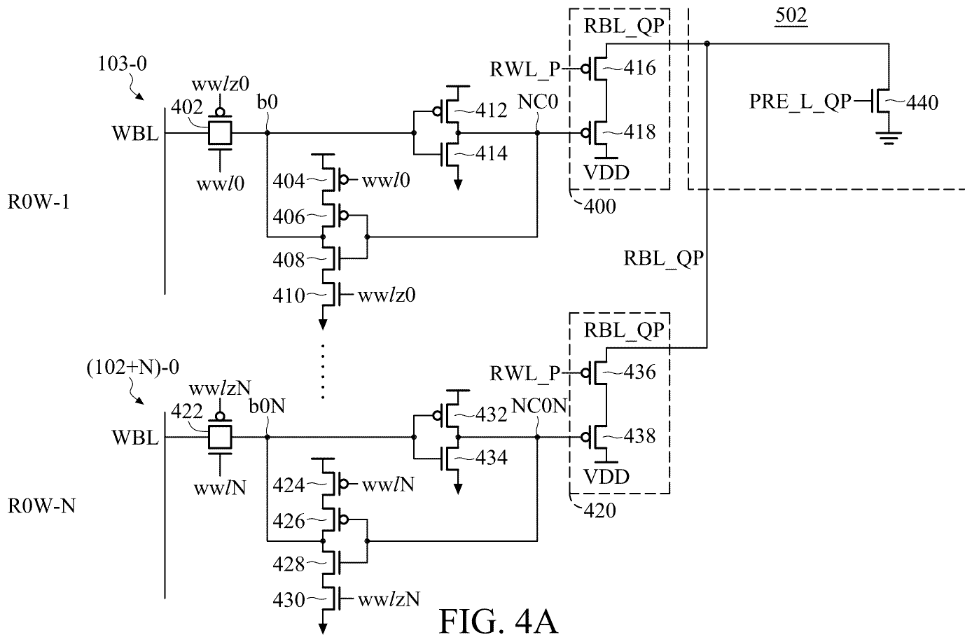

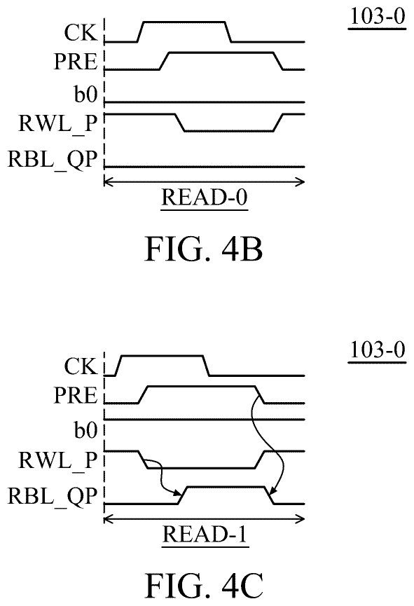

FIG. 4A is a circuit diagram of the P-bit cell 103-0 in FIG. 1 in accordance with some embodiments of the present invention. As shown in FIG. 4A, the P-bit cell 103-0 includes an PMOS stack 400, a pass transistor 402, a transistor 404, a transistor 406, a transistor 408, a transistor 410, a transistor 412, and a transistor 414. The pass transistor 402 is electrically connected to the word line WBL and is controlled by a write-word-line control signal wwl0 and a write-word-line control signal wwlz0. The PMOS stack 400 charges or discharges or maintains a bit line RBL_QP according to a read-word-line control signal RWL_P. The transistor 412 has a first end, a second end, and a control end. The transistor 412's first end is electrically connected to the voltage VDD. The transistor 412's second end is electrically connected to the PMOS stack 400 through a node NC0. The transistor 412's control end is electrically connected to the pass transistor 402 through a node b0. The transistor 414 has a first end, a second end, and a control end. The transistor 414's first end is electrically connected to the PMOS stack 400 through the node NC0. The transistor 414's second end is electrically connected to a ground. The transistor 414's control end is electrically connected to the pass transistor 402 through the node b0.

The transistor 404 has a first end, a second end, and a control end. The transistor 404's first end is electrically connected to the voltage VDD. The transistor 404's control end is electrically connected to the write-word-line control signal wwl0. The transistor 406 has a first end, a second end, and a control end. The transistor 406's first end is electrically connected to the second end of the transistor 404. The transistor 406's second end is electrically connected to the pass transistor 402 through the node b0. The transistor 406's control end is electrically connected to the PMOS stack 400 through the node NC0. The transistor 408 has a first end, a second end, and a control end. The transistor 408's first end is electrically connected to the pass transistor 402 through the node b0. The transistor 408's control end is electrically connected to the PMOS stack 400 through the node NC0. The transistor 410 has a first end, a second end, and a control end. The transistor 410's first end is electrically connected to the second end of the transistor 408. The transistor 410's second end is electrically connected to the ground. The transistor 410's control end is electrically connected to the write-word-line control signal wwlz0.

In some embodiments, the PMOS stack 400 includes a transistor 416 and a transistor 418. The transistor 416 has a first end, a second end, and a control end. The transistor 416's first end is electrically connected to the bit line RBL-QP. The transistor 416's control end is electrically connected to the read-word-line control signal RWL_P. The transistor 418 has a first end, a second end, and a control end. The transistor 418's first end is electrically connected to the second end of the transistor 416. The transistor 418's second end is electrically connected to the voltage VDD. The transistor 418's control end is electrically connected to the second end of the transistor 412, the control end of the transistor 406, and the control end of the transistor 408 through the node NC0. In some embodiments of FIG. 4A, the transistors 412, 404, 406, 416, and 418 are p-type transistors. The transistors 414, 408, and 410 are n-type transistors. The P-bit cells 103-0 and 105-0 are electrically connected to form the bit line RBL-QP[0]. The P-bit cells 103-N and 105-N are electrically connected to form the bit line RBL-QP[N].

In some embodiments, the bit line RBL-QP is electrically connected to the first end of a transistor 440. The second end of the transistor 440 is electrically connected to the ground. The transistor 440 is included in the output (IO) circuit (LIO) 502 in FIG. 5.

Similarly, the P-bit cell (102+N)-0 includes an PMOS stack 420, a pass transistor 422, a transistor 424, a transistor 426, a transistor 428, a transistor 430, a transistor 432, and a transistor 434. The pass transistor 422 is electrically connected to the word line WBL and is controlled by a write-word-line control signal wwlN and a write-word-line control signal wwlzN. The PMOS stack 420 charges or discharges or maintains a bit line RBL_QP according to a read-word-line control signal RWL_P. The transistor 432 has a first end, a second end, and a control end. The transistor 432's first end is electrically connected to the voltage VDD. The transistor 432's second end is electrically connected to the PMOS stack 420 through a node NC0N. The transistor 432's control end is electrically connected to the pass transistor 422 through a node b0N. The transistor 434 has a first end, a second end, and a control end. The transistor 434's first end is electrically connected to the PMOS stack 420 through the node NC0N. The transistor 434's second end is electrically connected to the ground. The transistor 434's control end is electrically connected to the pass transistor 422 through the node b0N.

The transistor 424 has a first end, a second end, and a control end. The transistor 424's first end is electrically connected to the voltage VDD. The transistor 424's control end is electrically connected to the write-word-line control signal wwlN. The transistor 426 has a first end, a second end, and a control end. The transistor 426's first end is electrically connected to the second end of the transistor 424. The transistor 426's second end is electrically connected to the pass transistor 422 through the node b0N. The transistor 426's control end is electrically connected to the PMOS stack 420 through the node NC0N. The transistor 428 has a first end, a second end, and a control end. The transistor 428's first end is electrically connected to the pass transistor 422 through the node b0N. The transistor 428's control end is electrically connected to the PMOS stack 420 through the node NC0N. The transistor 430 has a first end, a second end, and a control end. The transistor 430's first end is electrically connected to the second end of the transistor 428. The transistor 430's second end is electrically connected to the ground. The transistor 430's control end is electrically connected to the write-word-line control signal wwlzN.

In some embodiments, the PMOS stack 420 includes a transistor 436 and a transistor 438. The transistor 436 has a first end, a second end, and a control end. The transistor 436's first end is electrically connected to the bit line RBL-QP. The transistor 436's control end is electrically connected to the read-word-line control signal RWL_P. The transistor 438 has a first end, a second end, and a control end. The transistor 438's first end is electrically connected to the second end of the transistor 436. The transistor 438's second end is electrically connected to the voltage VDD. The transistor 438's control end is electrically connected to the second end of the transistor 432, the control end of the transistor 426, and the control end of the transistor 428 through the node NC0N. In some embodiments of FIG. 4A, the transistors 432, 424, 426, 436, and 438 are p-type transistors. The transistors 434, 428, and 430 are n-type transistors.

In some embodiments, the first end of the transistor 440 included in the LIO 502 is electrically connected to the P-bit cells 103-0, . . . , (102+N)-0.

FIG. 4B is a timing diagram of internal operations of the P-bit cell 103-0 in FIG. 1 during the read-zero operation (READ-0) in accordance with some embodiments of the present invention. In some embodiments, the read-zero operation (READ-0) is performed when the N-bit cells or the P-bit cells are storing zero. FIG. 4B illustrates the timing diagram of the clock signal CK, the pre-charge signal PRE, a voltage on the node b0, the read-word-line control signal RWL_P, and a voltage on the bit line RBL_QP during the read-zero operation (READ-0). As shown in FIG. 4B, the clock signal CK rises up from the logic low level to the logic high level first. The pre-charge signal PRE then rises up when the clock signal CK maintains at the logic high level. Next, the read-word-line control signal RWL_P pulls down after the pre-charge signal PRE rises up. The bit line RBL_QP is discharged to the logic low level at the start of the read-zero operation (READ-0). When the read-word-line control signal RWL_P pulls down, the PMOS stack 400 is turned off, causing the voltage on the bit line RBL_QP to stay at the logic low level. The voltage on the node b0 is always at the logic low level during the read-zero operation (READ-0). The voltage on the bit line RBL_QP stays at the logic low level during the read-zero operation (READ-0).

FIG. 4C is a timing diagram of internal operations of the P-bit cell 103-0 in FIG. 1 during the read-one operation (READ-1) in accordance with some embodiments of the present invention. In some embodiments, the read-one operation (READ-1) is performed when the N-bit cells or the P-bit cells are storing one. FIG. 4C illustrates the timing diagram of the clock signal CK, the pre-charge signal PRE, the voltage on the node b0, the read-word-line control signal RWL_P, and the voltage on the bit line RBL_QP during the read-one operation (READ-1). As shown in FIG. 4C, the clock signal CK rises up from the logic low level to the logic high level first. The pre-charge signal PRE then rises up when the clock signal CK maintains at the logic high level. The bit line RBL_QP is discharged to the logic low level at the start of the read-one operation (READ-1). When the read-word-line control signal RWL_N pulls down, the PMOS stack 400 is turned on, causing the voltage on the bit line RBL_QP to rise up to the logic high level. The voltage one the node b0 is always at the logic high level during the read-one operation (READ-1). The voltage on the bit line RBL_QP is charged from the logic low level to the logic high level during the read-one operation (READ-1).

FIG. 5A is a schematic diagram of an electronic device 500 including the logic cell array 100 in FIG. 1 and a read sensing circuit in accordance with some embodiments of the present invention. In some embodiments of FIG. 5A, the read sensing circuit is electrically connected to the logic cell array (CLA ARRAY) 100, a logic cell array 508, a logic cell array 510, and a logic cell array 512. The read sensing circuit determines outputs from the even rows of the logic cell array or the odd rows of the logic cell array, and converts logic levels on the bit line RBL_QN and the bit line RBL_QP during the read-zero operation or the read-one operation. As shown in FIG. 5A, the read sensing circuit in the electronic device 500 include a local input and output (IO) circuit (LIO) 502, a local IO circuit 506, and a global IO circuit 504. The local IO circuit 502 is electrically connected between the logic cell array 100 and the logic cell 508. The IO circuit 506 is electrically connected between the logic cell array 510 and the logic cell 512. The global IO circuit 504 is electrically connected to the local IO circuit 502 and the IO circuit 506.

The local IO circuit 502 converts logic levels on a bit line RBL_QN_L and a bit line RBL_QN_R based on a pre-charge signal PRE_QN during the read-zero operation or the read-one operation. The bit line RBL_QN_L is electrically connected to N-bit cells in the logic cell array 100. The bit line RBL_QN_R is electrically connected to N-bit cells in the logic cell array 508. The local IO circuit 502 converts the logic levels on a bit line RBL_QP_L and a bit line RBL_QP_R based on a pre-charge signal PRE_QP during the read-zero operation or the read-one operation. The bit line RBL_QP_L is electrically connected to P-bit cells in the logic cell array 100. The bit line RBL_QN_R is electrically connected to P-bit cells in the logic cell array 508.

Similarly, the local IO circuit 506 converts logic levels on a bit line RBL_QN_L and a bit line RBL_QN_R based on a pre-charge signal PRE_QN during the read-zero operation or the read-one operation. The bit line RBL_QN_L is electrically connected to N-bit cells in the logic cell array 510. The bit line RBL_QN_R is electrically connected to N-bit cells in the logic cell array 512. The local IO circuit 506 converts the logic levels on a bit line RBL_QP_L and a bit line RBL_QP_R based on a pre-charge signal PRE_QP during the read-zero operation or the read-one operation. The bit line RBL_QP_L is electrically connected to P-bit cells in the logic cell array 510. The bit line RBL_QN_R is electrically connected to P-bit cells in the logic cell array 512. The global IO circuit 504 determines outputs from the even rows of the logic cell array (for example, the logic cell 100 or 508 or 510 or 512) or the odd rows of the logic cell array based on a selection signal SEL_N and a selection signal SEL_P.

In some embodiments, the global IO circuit 504 outputs a read-result signal DO based on the selection signal SEL_N and the selection signal SEL_P, a global signal GBL_N_U, a global signal GBL_P_U, and data stored in the N-bit cells and the P-bit cells in the logic cell array 100 or 508. The local IO circuit 502 outputs the global signal GBL_N_U to the global IO circuit 504 based on the logic levels on the bit line RBL_QN_L in the logic cell array 100 or the logic levels on the bit line RBL_QN_R in the logic cell array 508. The local IO circuit 502 outputs the global signal GBL_P_U to the global IO circuit 504 based on the logic levels on the bit line RBL_QP_L in the logic cell array 100 or the logic levels on the bit line RBL_QP_R in the logic cell array 508.

Similarly, the global IO circuit 504 outputs the read-result signal DO based on the selection signal SEL_N and the selection signal SEL_P, a global signal GBL_N_D, a global signal GBL_P_D, and data stored in the N-bit cells and the P-bit cells of the logic cell array 510 or 512. The local IO circuit 506 outputs the global signal GBL_N_D to the global IO circuit 504 based on the logic levels on the bit line RBL_QN_L in the logic cell array 510 or the logic levels on the bit line RBL_QN_R in the logic cell array 512. The local IO circuit 506 outputs the global signal GBL_P_D to the global IO circuit 504 based on the logic levels on the bit line RBL_QP_L in the logic cell array 510 or the logic levels on the bit line RBL_QP_R the logic cell array 512.

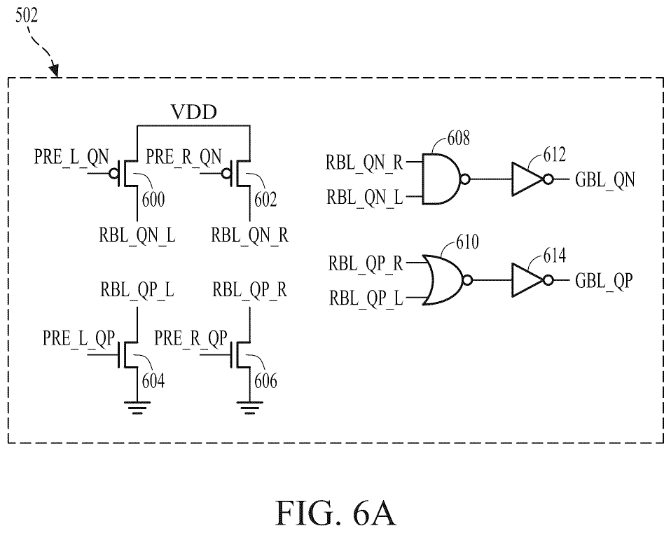

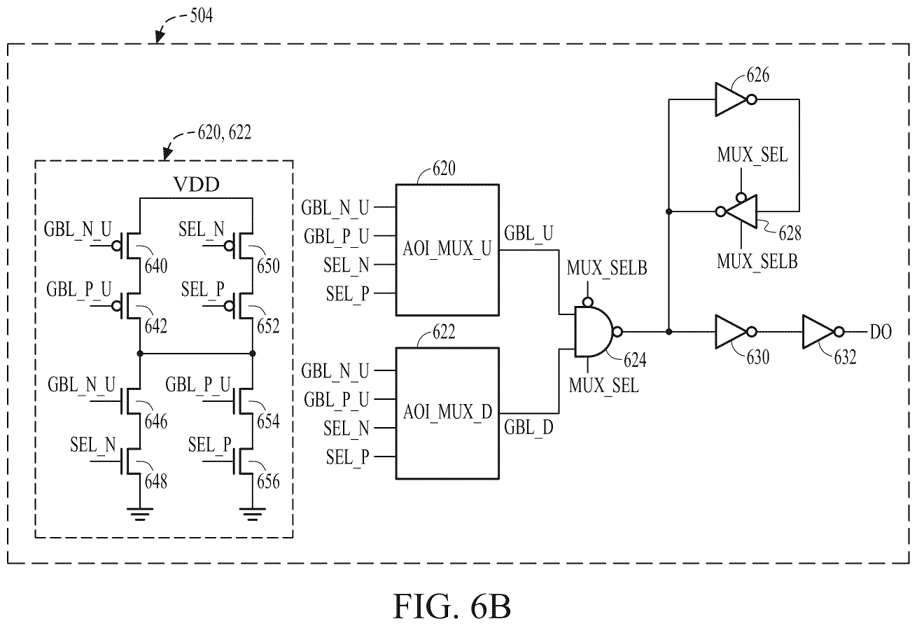

FIG. 6A is a circuit diagram of a local input and output (IO) circuit 502 included in the electronic device 500 in FIG. 5A in accordance with some embodiments of the present invention. As shown in FIG. 6A, the local IO circuit 502 includes a transistor 600, a transistor 602, a transistor 604, a transistor 606, a NAND gate 608, a NOR gate 610, an inverter 612, and an inverter 614. The transistor 600 has a first end, a second end, and a control end. The transistor 600's first end is electrically connected to the voltage VDD. The transistor 600's second end is electrically connected to a bit line RBL_QN_L. The transistor 600's control end is electrically connected to a pre-charge signal PRE_L_QN. The transistor 604 has a first end, a second end, and a control end. The transistor 604's first end is electrically connected to a bit line RBL_QP_L. The transistor 604's second end is electrically connected to a ground. The transistor 604's control end is electrically connected to a pre-charge signal PRE_L_QP. The transistor 602 has a first end, a second end, and a control end. The transistor 602's first end is electrically connected to the voltage VDD. The transistor 602's second end is electrically connected to a bit line RBL_QN_R. The transistor 602's control end is electrically connected to a pre-charge signal PRE_R_QN. The transistor 606 has a first end, a second end, and a control end. The transistor 606's first end is electrically connected to a bit line RBL_QP_R. The transistor 606's second end is electrically connected to the ground. The transistor 606's control end is electrically connected to a pre-charge signal PRE_R_QP.

The NAND gate 608 is electrically connected to the bit line RBL_QN_R and the bit line RBL_QN_L. The NAND gate 608 performs a NAND operation on the logic levels of the bit line RBL_QN_R and the bit line RBL_QN_L to obtain a first result. The inverter 612 is electrically connected to the NAND gate 608. The inverter 612 inverts the first result from the NAND gate 608 to output the global signal GBL_QN, which may be the same as the global signal GBL_N_U and the global signal GBL_N_D in FIG. 5A.

The NOR gate 610 is electrically connected to the bit line RBL_QP_R and the bit line RBL_QP_L. The NOR gate 610 performs a NOR operation on the logic levels of the bit line RBL_QP_R and the bit line RBL_QP_L to obtain a second result. The inverter 614 is electrically connected to the NOR gate 610. The inverter 614 inverts the second result from the NOR gate 610 to output the global signal GBL_QP, which may be the same as the global signal GBL_P_U and the global signal GBL_P_D in FIG. 5A.

FIG. 6B is a circuit diagram of a global IO circuit 504 included in the electronic device 500 in FIG. 5A in accordance with some embodiments of the present invention. As shown in FIG. 6B, the global IO circuit 504 includes a multiplexer (AOI_MUX_U) 620, a multiplexer (AOI_MUX_D) 622, a NAND gate 624, an inverter 626, an inverter 628, an inverter 630, and an inverter 632. The multiplexer 620 outputs a global signal GBL_U based on the global signal GBL_N_U from the local IO circuit 502, the global signal GBL_P_U from the local IO circuit 502, the selection signal SEL_N, and the selection signal SEL_P. The multiplexer 622 outputs a global signal GBL_D based on the global signal GBL_N_U from the local IO circuit 502, the global signal GBL_P_U from the local IO circuit 502, the selection signal SEL_N, and the selection signal SEL_P. The NAND gate 624 receives the global signal GBL_U and the global signal GBL_D and outputs a first intermediate signal by performing the NAND operation on the global signal GBL_U and the global signal GBL_D based on a mux selection signal MUX_SEL and a mux selection signal MUX_SELB.

The inverter 630 is electrically connected between the NAND gate 624 and the inverter 632. The inverter 626's input end is electrically connected to the NAND gate 624's output end. The inverter 626's output end is electrically connected to the inverter 628's input end. The inverter 628's output end is electrically connected to the NAND gate 624's output end and the inverter 630's input end. The inverter 628 is controlled by the mux selection signal MUX_SEL and the mux selection signal MUX_SELB. The first intermediate signal is inverted by both the inverter 630 and the inverter 632 to obtain the read-result signal DO.

In some embodiments, each of the multiplexer 620 and the multiplexer 622 includes a transistor 640, a transistor 642, a transistor 644, a transistor 646, a transistor 650, a transistor 652, a transistor 654, and a transistor 656. The transistor 640 has a first end, a second end, and a control end. The transistor 640's first end is electrically connected to the voltage VDD. The transistor 640's second end is electrically connected to the transistor 642's first end. The transistor 640's control end is electrically connected to the global signal GBL_N_U. The transistor 642's second end is electrically connected to the transistor 644's first end. The transistor 642's control end is electrically connected to the global signal GBL_P_U. The transistor 644's second end is electrically connected to the transistor 646's first end. The transistor 644's control end is electrically connected to the global signal GBL_N_U. The transistor 646's second end is electrically connected to the ground. The transistor 646's control end is electrically connected to the selection signal SEL_N.

The transistor 650's first end is electrically connected to the voltage VDD. The transistor 650's second end is electrically connected to the transistor 652's first end. The transistor 650's control end is electrically connected to the selection signal SEL_N. The transistor 652's second end is electrically connected to the transistor 654's first end. The transistor 652's control end is electrically connected to the selection signal SEL_P. The transistor 654's second end is electrically connected to the transistor 656's first end. The transistor 654's control end is electrically connected to the global signal GBL_P_U. The transistor 656's second end is electrically connected to the ground. The transistor 656's control end is electrically connected to the selection signal SEL_P. The transistor 640's second end is further electrically connected to the transistor 650's second end. The transistor 642's second end is further electrically connected to the transistor 652's second end.

FIG. 5B is a timing diagram of control signals for the electronic device 500 to read the N-bit cell 102-0 in FIG. 1 in accordance with some embodiments of the present invention. FIG. 5B illustrates the timing diagram of the clock signal CK, the selection signal SEL_P, the selection signal SEL_N, the mux selection signal MUX_SEL, the pre-charge signal PRE, the voltage on the bit line RBL_QN_L, the global signal GBL_QN, the global signal GBL_U, and the read-result signal DO during the read-zero operation (READ-0) and the read-one operation (READ-1). As shown in FIG. 5B, at the start of the read-zero operation (READ-0) and the read-one operation (READ-1), the voltage on the bit line RBL_QN_L is pre-charged to the logic high level, for example, “1”. Upon arrival of the clock signal CK, the pre-charge is turned off and the selection signal SEL_N rises up to the logic high level. The mux selection signal MUX-SEL also rises up to the logic high level. If the N-bit cell 102-0 is storing zero, the voltage on the bit line RBL_QN_L is discharged to the logic low level, which makes the global signal GBL_QN to the logic low level (for example, “0”), and makes the global signal GBL_U from the logic low level to the logic high level, so that the read-result signal DO becomes at the logic low level. If the N-bit cell 102-0 is storing one, the voltage on the bit line RBL_QN_L remains at the logic high level, the global signal GBL_QNstays at the logic high level, and the global signal GBL_U changes from the logic high level to the logic low level, so that the read-result signal DO becomes at the logic high level. The selection signal SEL_P is always at the logic low level during the read-zero operation (READ-0) and the read-one operation (READ-1).

FIG. 5C is a timing diagram of control signals for the electronic device 500 to read the P-bit cell 103-0 in FIG. 1 in accordance with some embodiments of the present invention. FIG. 5C illustrates the timing diagram of the clock signal CK, the selection signal SEL_P, the selection signal SEL_N, the mux selection signal MUX_SEL, the pre-charge signal PRE, the voltage on the bit line RBL_QN_L, the global signal GBL_QN, the global signal GBL_U, and the read-result signal DO during the read-zero operation (READ-0) and the read-one operation (READ-1). At the start of the read-zero operation (READ-0) and the read-one operation (READ-1), the voltage on the bit line RBL_QP_L is discharged to the logic low level, for example, “0”. Upon arrival of the clock signal CK, the pre-charge is turned on and the selection signal SEL_P rises up to the logic high level. The mux selection signal MUX-SEL also rises up to the logic high level. If the P-bit cell 103-0 is storing zero, the voltage on the bit line RBL_QP_L remains at the logic low level, the global signal GBL_QP remains at the logic low level, and the global signal GBL_U remains at the logic high level, so that the read-result signal DO becomes at the logic low level. If the P-bit cell 103-0 is storing one, the voltage on the bit line RBL_QP_L rises up to the logic high level, which makes the global signal GBL_QP to the logic high level (for example, “1”), and makes the global signal GBL_U from the logic high level to the logic low level, so that the read-result signal DO becomes at the logic high level.

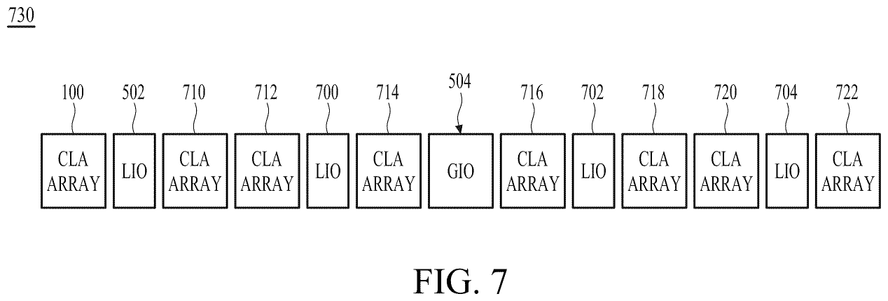

FIG. 7 is a schematic diagram of an electronic device 730 in accordance with some embodiments of the present invention. As shown in FIG. 7, the electronic device 730 includes the logic cell array 100, the local IO circuit 502, a logic cell array 710, a logic cell array 712, a local IO circuit 700, a logic cell array 714, the global IO circuit 504, a logic cell 716, a local IO circuit 702, a logic cell array 718, a logic cell array 720, a local IO circuit 704, and a logic cell array 722. In some embodiments, the electronic device 730 is a multi-bank implementation of custom logic cells. The local IO circuit 502 is electrically connected between the logic cell 100 and the logic cell 710. The local IO circuit 700 is electrically connected between the logic cell 712 and the logic cell array 714. The local IO circuit 702 is electrically connected between the logic cell array 716 and the logic cell array 718. The local IO circuit 704 is electrically connected between the logic cell array 720 and the logic cell array 722. The global IO circuit 504 is electrically connected to the local IO circuit 502, the local IO circuit 700, the local IO circuit 702, and the local IO circuit 704.

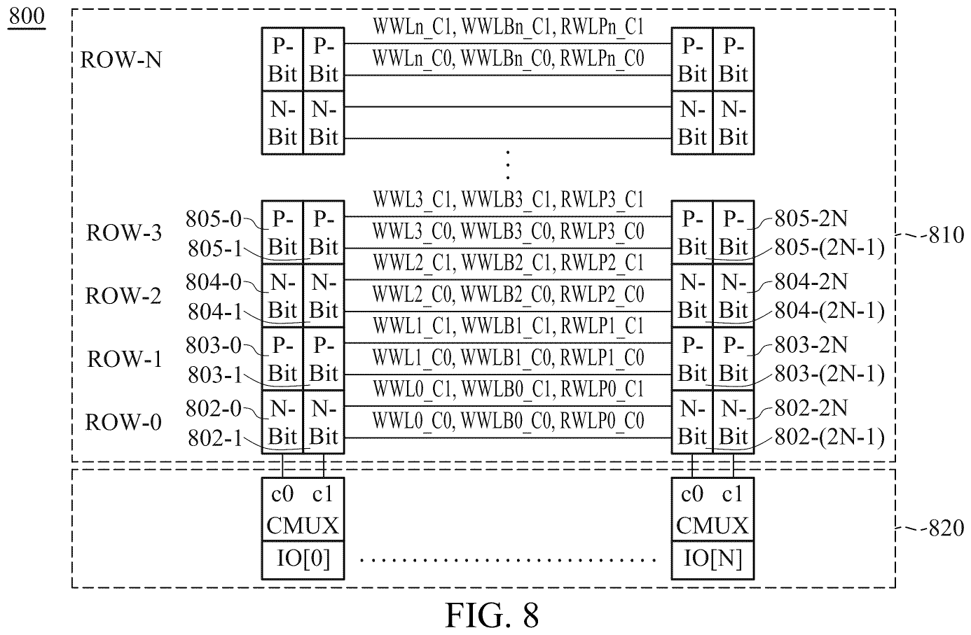

FIG. 8 is a schematic diagram of a logic cell array 810 included in an electronic device 800 in accordance with some embodiments of the present invention. The electronic device 800 includes a logic cell array 810 and input and output (IO) circuits 820. The logic cell array 810 includes a plurality of N-bit cells and a plurality of P-bit cells. For example, the logic cell array 810 includes N-bit cells 802-0, 802-1, . . . , 802-(2N-1), 802-2N and N-bit cells 804-0, 804-1, . . . , 804-(2N-1), 804-2N. The logic cell array 810 includes P-bit cells 803-0, 803-1, . . . , 803-(2N-1), 803-2N and P-bit cells 805-0, 805-1, . . . , 805-(2N-1), 805-2N. The N-bit cells and the P-bit cells are alternately row-wise to constitute one column of the logic cell array 810. The N-bit cells are disposed on even rows of the logic cell array 810, and the P-bit cells are disposed on odd rows of the logic cell array 810.

For example, FIG. 8 illustrates that the logic cell array 810 has N rows, for example, including a row ROW-0, a row ROW-1, a row ROW-2, a row ROW-3, . . . , ROW-n. The N-bit cells 802-0, 802-1, . . . , 802-(2N-1), 802-2N are disposed in the row ROW-0. The P-bit cells 803-0, 803-1, . . . , 803-(2N-1), 803-2N are disposed in the row ROW-1. The N-bit cells 804-0, 804-1, . . . , 804-(2N-1), 804-2N are disposed in the row ROW-2. The P-bit cells 805-0, 805-1, . . . , 805-(2N-1), 805-2N are disposed in the row ROW-3. Furthermore, some other N N-bit cells in the logic cell array 810 are disposed in the row ROW-(N-1), and some other N P-bit cells in the logic cell array 810 are disposed in the row ROW-N.

The N-bit cells 802-0, . . . , 802-(2N-1) are controlled by write-word-line control signals WWL0_C0 and WWLB0_C0 and a read-word-line control signal RWLP0_C0. The N-bit cells 802-1, . . . , 802-2N are controlled by write-word-line control signals WWL0_C1 and WWLB0_C1 and a read-word-line control signal RWLP0_C1. The P-bit cells 803-0, . . . , 803-(2N-1) are controlled by write-word-line control signals WWL1_C0 and WWLB1_C0 and a read-word-line control signal RWLP1_C0. The P-bit cells 803-1, . . . , 803-2N are controlled by write-word-line control signals WWL1_C1 and WWLB1_C1 and a read-word-line control signal RWLP1_C1. The N-bit cells 804-0, . . . , 804-(2N-1) are controlled by write-word-line control signals WWL2_C0 and WWLB2_C0 and a read-word-line control signal RWLP2_C0. The N-bit cells 804-1, . . . , 804-2N are controlled by write-word-line control signals WWL2_C1 and WWLB2_C1 and a read-word-line control signal RWLP2_C1. The P-bit cells 805-0, . . . , 805-(2N-1) are controlled by write-word-line control signals WWL3_C0 and WWLB3_C0 and a read-word-line control signal RWLP3_C0. The P-bit cells 805-1, . . . , 805-2N are controlled by write-word-line control signals WWL3_C1 and WWLB3_C1 and a read-word-line control signal RWLP3_C1. Half of the P-bit cells in the row ROW-N are controlled by write-word-line control signals WWLn_C0 and WWLBn_C0 and a read-word-line control signal RWLPn_C0. The other half of the P-bit cells in the row ROW-N are controlled by write-word-line control signals WWLn_C1 and WWLBn_C1 and a read-word-line control signal RWLPn_C1.

The IO circuits 820 are electrically connected to the logic cell array 810. The IO circuits 820 determines outputs from the even rows of the logic cell array 810 or the odd rows of the logic cell array 810, and converts logic levels on a bit line RBL_QN and a bit line RBL_QP during the read-zero operation or the read-one operation. The IO circuits 820 include IO circuits IO[0], . . . , IO[N]. Each of the IO circuits IO[0], . . . , IO[N] includes a connection multiplexer (CMUX) with output nodes c0 and c1. For example, the IO circuit IO[0] is electrically connected to the N-bit cell 802-0 through the node c0. The IO circuit IO[0] is electrically connected to the N-bit cell 802-1 through the node c1. The IO circuit IO[N] is electrically connected to the N-bit cell 802-(2N-1) through the node c0. The IO circuit IO[N] is electrically connected to the N-bit cell 802-2N through the node c1. In some embodiments, the electronic device 800 is a static random-access memory (SRAM), but the present invention is not limited thereto. In some embodiments, the electronic device 800 is a custom logic array (CLA) with higher mux (mux-2) architecture. That is, the CLA with higher mux (mux-2) architecture has two sets of word lines.

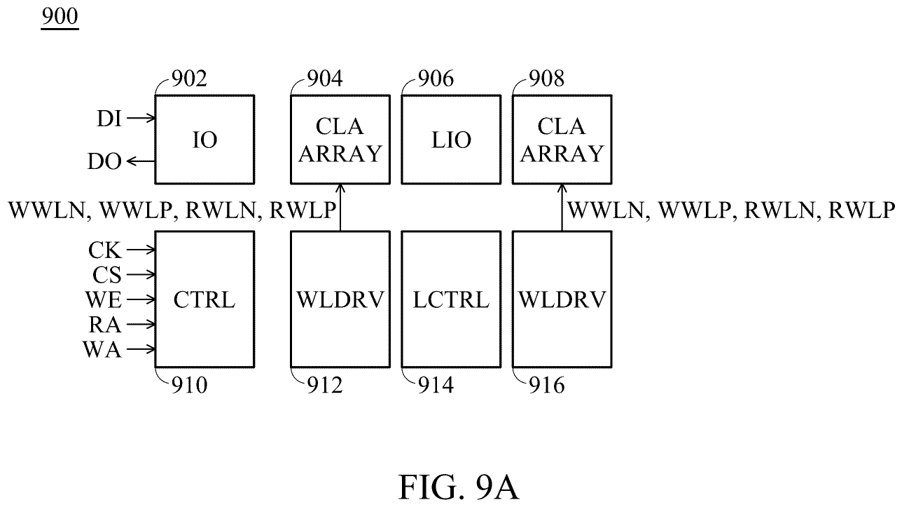

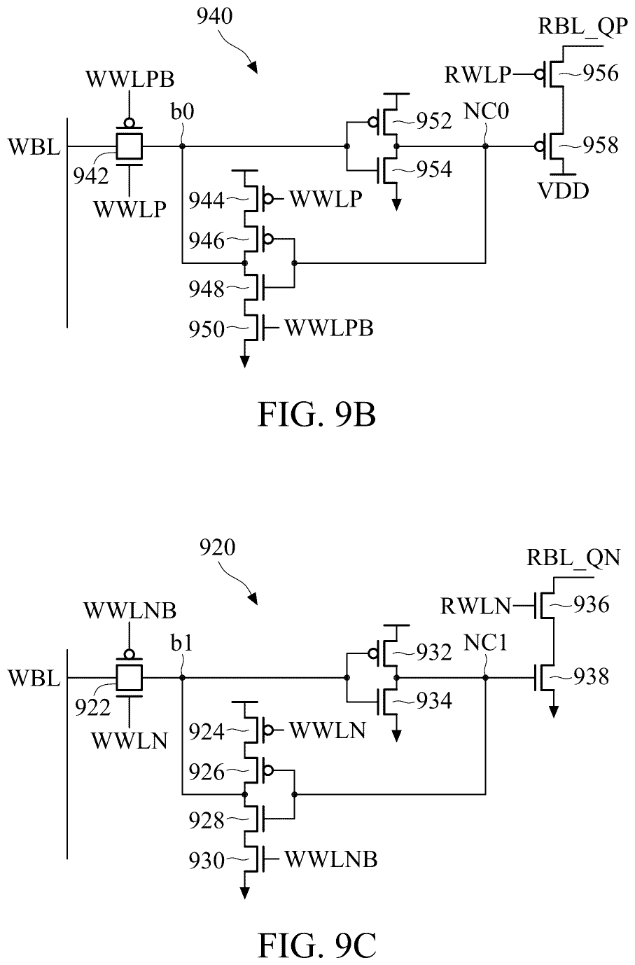

FIG. 9A is a schematic diagram of an electronic device 900 in accordance with some embodiments of the present invention. As shown in FIG. 9A, the electronic device 900 includes an IO circuit 902, a logic cell array 904, a local IO circuit 906, a logic cell array 908, a controller (CTRL) 910, a word line driver (WLDRV) 912, a local controller (LCTRL) 914, and a word line driver 916. In some embodiments, the controller 910 receives the clock signal CK, a signal CS, a signal WE, a signal RA, and a signal WA. The controller 910 sends corresponding control signals to the local controller 914 based on the clock signal CK, the signal CS, the signal WE, the signal RA, and the signal WA. The local controller 914 then enables the word line driver 912 to send write-word-line control signals WWLN and WWLP and read-word-line control signals RWLN and RWLP to the logic cell array 904. The local controller 914 also enables the word line driver 916 to send write-word-line control signals WWLN and WWLP and read-word-line control signals RWLN and RWLP to the logic cell array 908. The IO circuit 902 outputs the read-result signal DO during the read operation, and receives the input data DI during the write operation. In some embodiments, the electronic device 900 a single-port custom logic array (CLA) with one read and one write (1RW) function.

FIG. 9B is a circuit diagram of a P-bit cell 940 in a logic cell array 904 in FIG. 9A in accordance with some embodiments of the present invention. As shown in FIG. 9B, the P-bit cell 940 includes a pass transistor 942, a transistor 944, a transistor 946, a transistor 948, a transistor 950, a transistor 952, a transistor 954, a transistor 956, and transistor 958. The pass transistor 942 is electrically connected to the word line WBL and is controlled by a write-word-line control signal WWLP and a write-word-line control signal WWLPB. The transistors 956 and 958 charge or discharge or maintain a bit line RBL_QP according to a read-word-line control signal RWLP. The transistor 952 has a first end, a second end, and a control end. The transistor 952's first end is electrically connected to the voltage VDD. The transistor 952's second end is electrically connected to the transistor 958's control end through a node NC0. The transistor 952's control end is electrically connected to the pass transistor 942 through a node b0. The transistor 954 has a first end, a second end, and a control end. The transistor 954's first end is electrically connected to the transistor 958's control end through the node NC0. The transistor 954's second end is electrically connected to a ground. The transistor 954's control end is electrically connected to the pass transistor 942 through the node b0.

The transistor 944 has a first end, a second end, and a control end. The transistor 944's first end is electrically connected to the voltage VDD. The transistor 944's control end is electrically connected to the write-word-line control signal WWLP. The transistor 946 has a first end, a second end, and a control end. The transistor 946's first end is electrically connected to the second end of the transistor 944. The transistor 946's second end is electrically connected to the pass transistor 942 through the node b0. The transistor 946's control end is electrically connected to the transistor 958's control end through the node NC0. The transistor 948 has a first end, a second end, and a control end. The transistor 948's first end is electrically connected to the pass transistor 942 through the node b0. The transistor 948's control end is electrically connected to the transistor 958's control end through the node NC0. The transistor 950 has a first end, a second end, and a control end. The transistor 950's first end is electrically connected to the second end of the transistor 948. The transistor 950's second end is electrically connected to the ground. The transistor 950's control end is electrically connected to the write-word-line control signal WWLPB.

The transistor 956 has a first end, a second end, and a control end. The transistor 956's first end is electrically connected to the bit line RBL-QP. The transistor 956's control end is electrically connected to the read-word-line control signal RWLP. The transistor 958 has a first end, a second end, and a control end. The transistor 958's first end is electrically connected to the second end of the transistor 956. The transistor 958's second end is electrically connected to the voltage VDD. The transistor 958's control end is electrically connected to the second end of the transistor 952, the control end of the transistor 946, and the control end of the transistor 948 through the node NC0. In some embodiments of FIG. 9B, the transistors 944, 946, 952, 956 and 958 are p-type transistors. The transistors 948, 950, and 954 are n-type transistors. The bit line RBL-QP is electrically connected to the P-bit cells in one column of the logic cell array 904.

FIG. 9C is a circuit diagram of an N-bit cell 920 in the logic cell array 904 in FIG. 9A in accordance with some embodiments of the present invention. As shown in FIG. 9C, the N-bit cell 920 includes a pass transistor 922, a transistor 924, a transistor 926, a transistor 928, a transistor 930, a transistor 932, a transistor 934, a transistor 936, and a transistor 938. The pass transistor 922 is electrically connected to a word line WBL and is controlled by a write-word-line control signal WWLN and a write-word-line control signal WWLNB. The transistor 936 and the transistor 938 charge or discharge or maintain a bit line RBL_QN according to a read-word-line control signal RWLN. The transistor 932 has a first end, a second end, and a control end. The transistor 932's first end is electrically connected to a voltage VDD. The transistor 932's second end is electrically connected to the transistor 936's second end through a node NC1. The transistor 932's control end is electrically connected to the pass transistor 922 through a node b1. The transistor 934 has a first end, a second end, and a control end. The transistor 934's first end is electrically connected to the transistor 936's second end through the node NC1. The transistor 934's second end is electrically connected to a ground. The transistor 934's control end is electrically connected to the pass transistor 922 through the node b1.

The transistor 924 has a first end, a second end, and a control end. The transistor 924's first end is electrically connected to the voltage VDD. The transistor 924's control end is electrically connected to the write-word-line control signal WWLN. The transistor 926 has a first end, a second end, and a control end. The transistor 926's first end is electrically connected to the second end of the transistor 924. The transistor 926's second end is electrically connected to the pass transistor 922 through the node b1. The transistor 926's control end is electrically connected to the transistor 938's control end through the node NC1. The transistor 928 has a first end, a second end, and a control end. The transistor 928's first end is electrically connected to the pass transistor 302 through the node b1. The transistor 928's control end is electrically connected to the transistor 938's control end through the node NC1. The transistor 930 has a first end, a second end, and a control end. The transistor 930's first end is electrically connected to the second end of the transistor 928. The transistor 930's second end is electrically connected to the ground. The transistor 930's control end is electrically connected to the write-word-line control signal WWLNB.

The transistor 936 has a first end, a second end, and a control end. The transistor 936's first end is electrically connected to the bit line RBL-QN. The transistor 936's control end is electrically connected to the read-word-line control signal RWLN. The transistor 938 has a first end, a second end, and a control end. The transistor 938's first end is electrically connected to the second end of the transistor 936. The transistor 938's second end is electrically connected to the ground. The transistor 938's control end is electrically connected to the second end of the transistor 932, the control end of the transistor 926, and the control end of the transistor 928 through the node NC1. In some embodiments of FIG. 9C, the transistors 924, 926, and 932 are p-type transistors. The transistors 928, 930, 934, 936, and 938 are n-type transistors. The bit line RBL-QN is electrically connected to the N-bit cells in one column of the logic cell array 904.

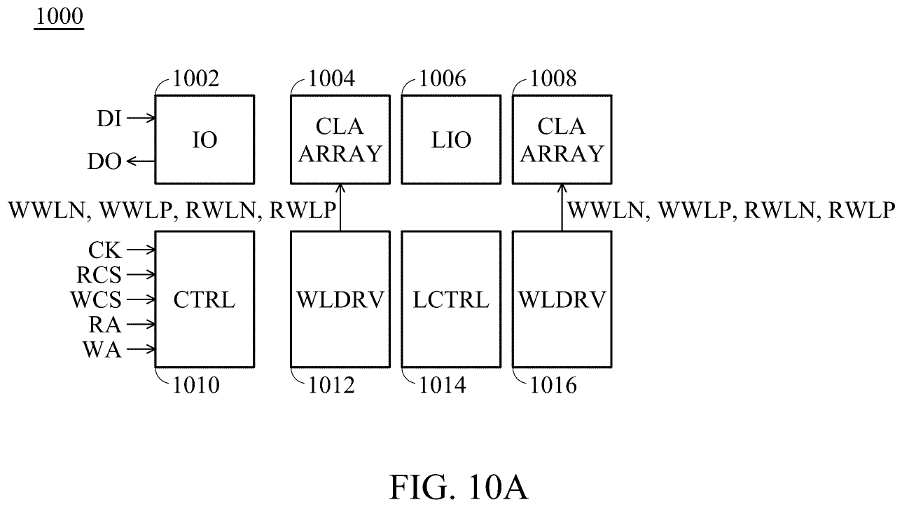

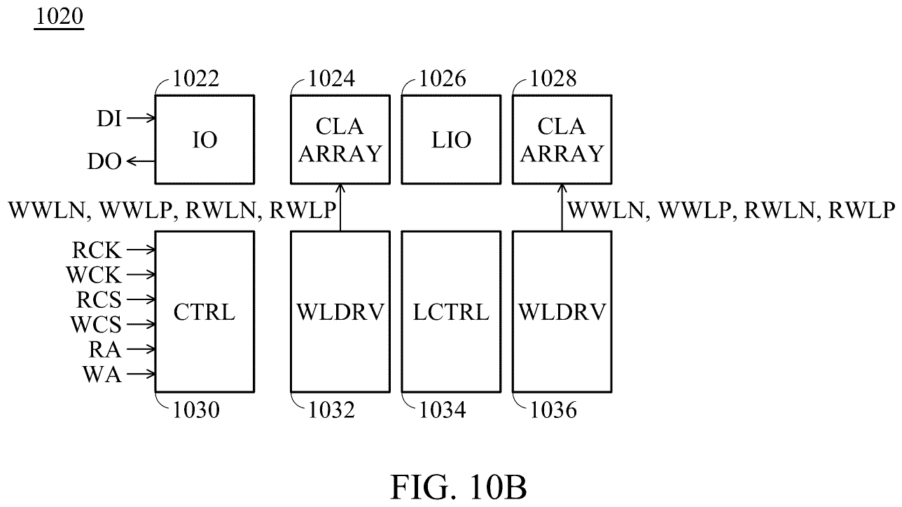

FIG. 10A is a schematic diagram of an electronic device 1000 in accordance with some embodiments of the present invention. As shown in FIG. 10A, the electronic device 1000 includes an IO circuit 1002, a logic cell array 1004, a local IO circuit 1006, a logic cell array 1008, a controller (CTRL) 1010, a word line driver (WLDRV) 1012, a local controller (LCTRL) 1014, and a word line driver 1016. In some embodiments, the controller 1010 receives the clock signal CK, a signal RCS, a signal WCS, a signal RA, and a signal WA. The controller 1010 sends corresponding control signals to the local controller 1014 based on the clock signal CK, the signal RCS, the signal WCS, the signal RA, and the signal WA. The local controller 1014 then enables the word line driver 1012 to send write-word-line control signals WWLN and WWLP and read-word-line control signals RWLN and RWLP to the logic cell array 1004. The local controller 1014 also enables the word line driver 1016 to send write-word-line control signals WWLN and WWLP and read-word-line control signals RWLN and RWLP to the logic cell array 1008. The IO circuit 1002 outputs the read-result signal DO during the read operation, and receives the input data DI during the write operation. In some embodiments, the electronic device 1000 is a type-1 two-port custom logic array (CLA) with one read and one write (1RW) function.

FIG. 10B is a schematic diagram of an electronic device 1020 in accordance with some embodiments of the present invention. As shown in FIG. 10B, the electronic device 1020 includes an IO circuit 1022, a logic cell array 1024, a local IO circuit 1026, a logic cell array 1028, a controller (CTRL) 1030, a word line driver (WLDRV) 1032, a local controller (LCTRL) 1034, and a word line driver 1036. In some embodiments, the controller 1030 receives a signal RCK, a signal WCK, a signal RCS, a signal WCS, a signal RA, and a signal WA. The controller 1030 sends corresponding control signals to the local controller 1034 based on the signal RCK, the signal WCK, the signal RCS, the signal WCS, the signal RA, and the signal WA. The local controller 1034 then enables the word line driver 1032 to send write-word-line control signals WWLN and WWLP and read-word-line control signals RWLN and RWLP to the logic cell array 1024. The local controller 1034 also enables the word line driver 1036 to send write-word-line control signals WWLN and WWLP and read-word-line control signals RWLN and RWLP to the logic cell array 1028. The IO circuit 1022 outputs the read-result signal DO during the read operation, and receives the input data DI during the write operation. In some embodiments, the electronic device 1020 is a type-2 two-port custom logic array (CLA) with one read and one write (1RW) function.

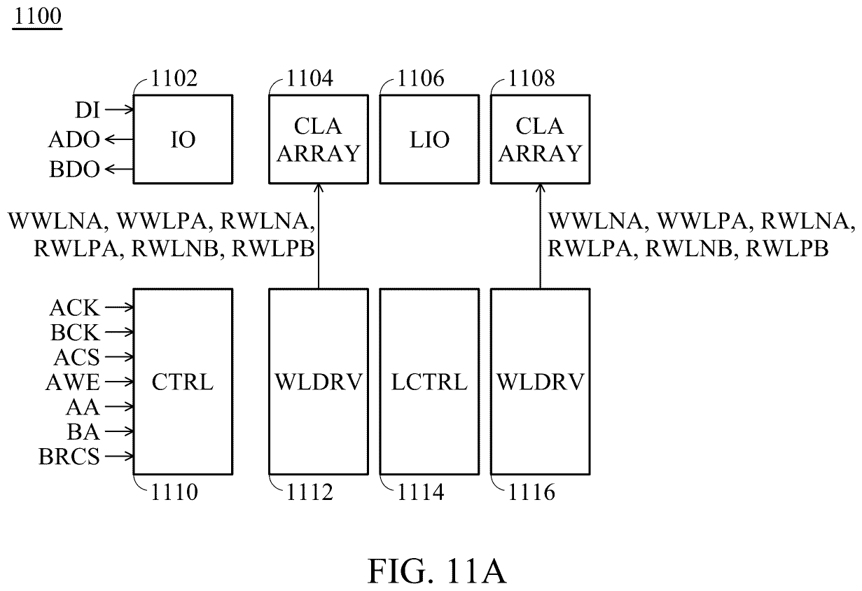

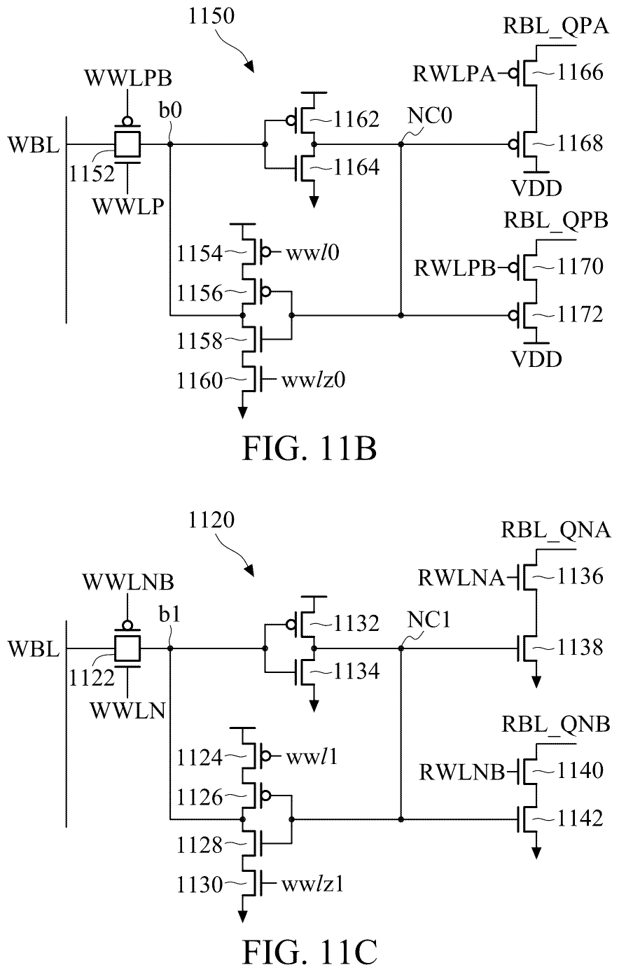

FIG. 11A is a schematic diagram of an electronic device 1100 in accordance with some embodiments of the present invention. As shown in FIG. 11A, the electronic device 1100 includes an IO circuit 1102, a logic cell array 1104, a local IO circuit 1106, a logic cell array 1108, a controller (CTRL) 1110, a word line driver (WLDRV) 1112, a local controller (LCTRL) 1114, and a word line driver 1116. In some embodiments, the controller 1110 receives a clock signal ACK, a clock signal BCK, a signal ACS, a signal AWE, a signal AA, a signal BA, and a signal BRCS. The controller 1110 sends corresponding control signals to the local controller 1114 based on the clock signal ACK, the clock signal BCK, the signal ACS, the signal AWE, the signal AA, the signal BA, and the signal BRCS. The local controller 1114 then enables the word line driver 1112 to send write-word-line control signals WWLNA and WWLPA and read-word-line control signals RWLNA, RWLPA, RWLNB, RWLPB to the logic cell array 1104. The local controller 1114 also enables the word line driver 1116 to send write-word-line control signals WWLN and WWLP and read-word-line control signals RWLNA, RWLPA, RWLNB, RWLPB to the logic cell array 1108. The IO circuit 1102 outputs a read-result signal ADO and a read-result signal BDO during the read operation, and receives the input data DI during the write operation. In some embodiments, the electronic device 1100 a multi-port custom logic array (CLA) with one read and one read-write (1R1RW) function.

FIG. 11B is a circuit diagram of a P-bit cell 1150 in a logic cell array 1104 in FIG. 11A in accordance with some embodiments of the present invention. As shown in FIG. 11B, the P-bit cell 1150 includes a pass transistor 1152, a transistor 1154, a transistor 1156, a transistor 1158, a transistor 1160, a transistor 1162, a transistor 1164, a transistor 1166, a transistor 1168, a transistor 1170, and a transistor 1172. The pass transistor 1152 is electrically connected to the word line WBL and is controlled by a write-word-line control signal WWLP and a write-word-line control signal WWLPB. The transistors 1166 and 1168 charge or discharge or maintain a bit line RBL_QPA according to a read-word-line control signal RWLPA. The transistors 1170 and 1172 charge or discharge or maintain a bit line RBL_QPB according to a read-word-line control signal RWLPB.

The transistor 1162 has a first end, a second end, and a control end. The transistor 1162's first end is electrically connected to the voltage VDD. The transistor 1162's second end is electrically connected to the transistor 1168's control end through a node NC0. The transistor 1162's control end is electrically connected to the pass transistor 1152 through a node b0. The transistor 1164 has a first end, a second end, and a control end. The transistor 1164's first end is electrically connected to the transistor 1168's control end through the node NC0. The transistor 1164's second end is electrically connected to a ground. The transistor 1164's control end is electrically connected to the pass transistor 1152 through the node b0.

The transistor 1154 has a first end, a second end, and a control end. The transistor 1154's first end is electrically connected to the voltage VDD. The transistor 1154's control end is electrically connected to the write-word-line control signal wwl0. The transistor 1156 has a first end, a second end, and a control end. The transistor 1156's first end is electrically connected to the second end of the transistor 1154. The transistor 1156's second end is electrically connected to the pass transistor 1152 through the node b0. The transistor 1156's control end is electrically connected to the transistor 1168's control end through the node NC0. The transistor 1158 has a first end, a second end, and a control end. The transistor 1158's first end is electrically connected to the pass transistor 1152 through the node b0. The transistor 1158's control end is electrically connected to the transistor 1168's control end through the node NC0. The transistor 1160 has a first end, a second end, and a control end. The transistor 1160's first end is electrically connected to the second end of the transistor 1158. The transistor 1160's second end is electrically connected to the ground. The transistor 1160's control end is electrically connected to the write-word-line control signal wwlz0.

The transistor 1166's first end is electrically connected to the bit line RBL-QPA. The transistor 1166's control end is electrically connected to the read-word-line control signal RWLPA. The transistor 1168 has a first end, a second end, and a control end. The transistor 1168's first end is electrically connected to the second end of the transistor 1166. The transistor 1168's second end is electrically connected to the voltage VDD. The transistor 1168's control end is electrically connected to the second end of the transistor 1162, the control end of the transistor 1156, and the control end of the transistor 1158 through the node NC0. The transistor 1170's first end is electrically connected to the bit line RBL-QPB. The transistor 1170's control end is electrically connected to the read-word-line control signal RWLPB. The transistor 1172 has a first end, a second end, and a control end. The transistor 1172's first end is electrically connected to the second end of the transistor 1170. The transistor 1172's second end is electrically connected to the voltage VDD. The transistor 1172's control end is electrically connected to the second end of the transistor 1162, the control end of the transistor 1156, and the control end of the transistor 1158 through the node NC0.In some embodiments of FIG. 11B, the transistors 1154, 1156, 1162, 1166, 1168, 1170 and 1172 are p-type transistors. The transistors 1158, 1160, and 1164 are n-type transistors. The bit lines RBL_QPA and RBL_QPB are electrically connected to the P-bit cells in one column of the logic cell array 1104.

FIG. 11C is a circuit diagram of an N-bit cell 1120 in the logic cell array 1104 in FIG. 11A in accordance with some embodiments of the present invention. As shown in FIG. 11C, the N-bit cell 1120 includes a pass transistor 1122, a transistor 1124, a transistor 1126, a transistor 1128, a transistor 1130, a transistor 1132, a transistor 1134, a transistor 1136, a transistor 1138, a transistor 1140, and a transistor 1142. The pass transistor 1122 is electrically connected to the word line WBL and is controlled by a write-word-line control signal WWLP and a write-word-line control signal WWLPB. The transistors 1136 and 1138 charge or discharge or maintain a bit line RBL_QPA according to a read-word-line control signal RWLPA. The transistors 1140 and 1142 charge or discharge or maintain a bit line RBL_QPB according to a read-word-line control signal RWLPB.

The transistor 1132 has a first end, a second end, and a control end. The transistor 1132's first end is electrically connected to the voltage VDD. The transistor 1132's second end is electrically connected to the transistor 1138's control end through a node NC1. The transistor 1132's control end is electrically connected to the pass transistor 1122 through a node b1. The transistor 1134 has a first end, a second end, and a control end. The transistor 1134's first end is electrically connected to the transistor 1138's control end through the node NC1. The transistor 1134's second end is electrically connected to a ground. The transistor 1134's control end is electrically connected to the pass transistor 1122 through the node b1.

The transistor 1124 has a first end, a second end, and a control end. The transistor 1124's first end is electrically connected to the voltage VDD. The transistor 1124's control end is electrically connected to the write-word-line control signal wwl1. The transistor 1126 has a first end, a second end, and a control end. The transistor 1126's first end is electrically connected to the second end of the transistor 1124. The transistor 1126's second end is electrically connected to the pass transistor 1122 through the node b1. The transistor 1126's control end is electrically connected to the transistor 1138's control end through the node NC1. The transistor 1128 has a first end, a second end, and a control end. The transistor 1128's first end is electrically connected to the pass transistor 1122 through the node b1. The transistor 1128's control end is electrically connected to the transistor 1138's control end through the node NC1. The transistor 1130 has a first end, a second end, and a control end. The transistor 1130's first end is electrically connected to the second end of the transistor 1128. The transistor 1130's second end is electrically connected to the ground. The transistor 1130's control end is electrically connected to the write-word-line control signal wwlz1.

The transistor 1136's first end is electrically connected to the bit line RBL-QNA. The transistor 1136's control end is electrically connected to the read-word-line control signal RWLNA. The transistor 1138 has a first end, a second end, and a control end. The transistor 1138's first end is electrically connected to the second end of the transistor 1136. The transistor 1138's second end is electrically connected to the ground. The transistor 1138's control end is electrically connected to the second end of the transistor 1132, the control end of the transistor 1126, and the control end of the transistor 1128 through the node NC1. The transistor 1140's first end is electrically connected to the bit line RBL-QNB. The transistor 1140's control end is electrically connected to the read-word-line control signal RWLNB. The transistor 1142 has a first end, a second end, and a control end. The transistor 1142's first end is electrically connected to the second end of the transistor 1140. The transistor 1142's second end is electrically connected to the ground. The transistor 1142's control end is electrically connected to the second end of the transistor 1132, the control end of the transistor 1126, and the control end of the transistor 1128 through the node NC1. In some embodiments of FIG. 11C, the transistors 1124, 1126, and 1132 are p-type transistors. The transistors 1128, 1130, 1132, 1136, 1138, 1149, and 1142 are n-type transistors. The bit lines RBL_QPA and RBL_QPB are electrically connected to the P-bit cells in one column of the logic cell array 1104.

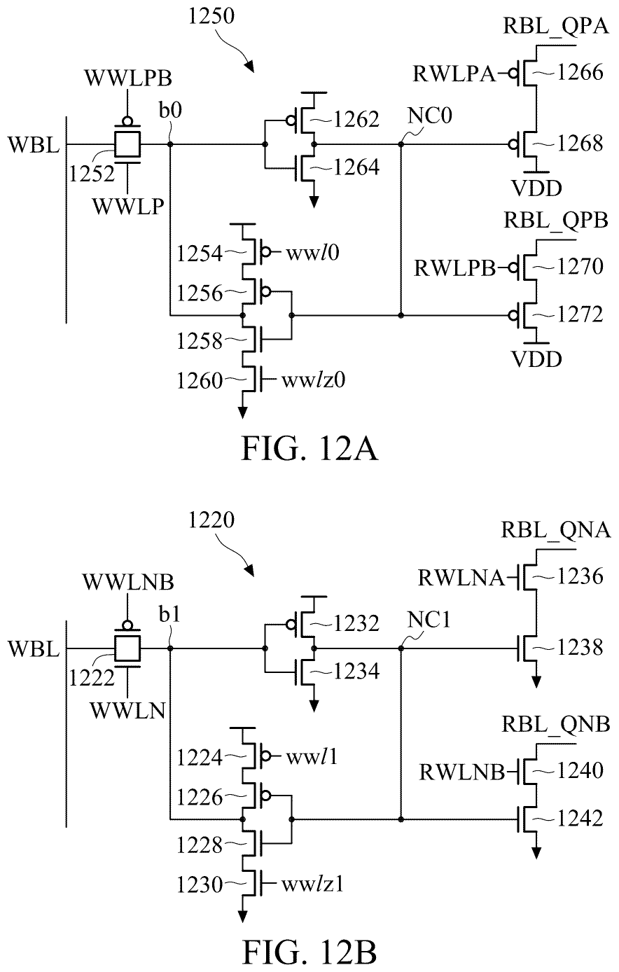

FIG. 12A is a circuit diagram of a P-bit cell 1250 in an 2R1W logic cell array in accordance with some embodiments of the present invention. As shown in FIG. 12A, the P-bit cell 1250 includes a pass transistor 1252, a transistor 1254, a transistor 1256, a transistor 1258, a transistor 1260, a transistor 1262, a transistor 1264, a transistor 1266, a transistor 1268, a transistor 1270, and a transistor 1272. The pass transistor 1252 is electrically connected to the word line WBL and is controlled by a write-word-line control signal WWLP and a write-word-line control signal WWLPB. The transistors 1266 and 1268 charge or discharge or maintain a bit line RBL_QPA according to a read-word-line control signal RWLPA. The transistors 1270 and 1272 charge or discharge or maintain a bit line RBL_QPB according to a read-word-line control signal RWLPB.

The transistor 1262 has a first end, a second end, and a control end. The transistor 1262's first end is electrically connected to the voltage VDD. The transistor 1262's second end is electrically connected to the transistor 1268's control end through a node NC0. The transistor 1262's control end is electrically connected to the pass transistor 1252 through a node b0. The transistor 1264 has a first end, a second end, and a control end. The transistor 1264's first end is electrically connected to the transistor 1268's control end through the node NC0. The transistor 1264's second end is electrically connected to a ground. The transistor 1264's control end is electrically connected to the pass transistor 1152 through the node b0.

The transistor 1254 has a first end, a second end, and a control end. The transistor 1254's first end is electrically connected to the voltage VDD. The transistor 1254's control end is electrically connected to the write-word-line control signal wwl0. The transistor 1256 has a first end, a second end, and a control end. The transistor 1256's first end is electrically connected to the second end of the transistor 1254. The transistor 1256's second end is electrically connected to the pass transistor 1252 through the node b0. The transistor 1256's control end is electrically connected to the transistor 1268's control end through the node NC0. The transistor 1258 has a first end, a second end, and a control end. The transistor 1258's first end is electrically connected to the pass transistor 1252 through the node b0. The transistor 1258's control end is electrically connected to the transistor 1268's control end through the node NC0. The transistor 1260 has a first end, a second end, and a control end. The transistor 1260's first end is electrically connected to the second end of the transistor 1258. The transistor 1260's second end is electrically connected to the ground. The transistor 1260's control end is electrically connected to the write-word-line control signal wwlz0.

The transistor 1266's first end is electrically connected to the bit line RBL-QPA. The transistor 1266's control end is electrically connected to the read-word-line control signal RWLPA. The transistor 1268 has a first end, a second end, and a control end. The transistor 1268's first end is electrically connected to the second end of the transistor 1266. The transistor 1268's second end is electrically connected to the voltage VDD. The transistor 1168's control end is electrically connected to the second end of the transistor 1262, the control end of the transistor 1256, and the control end of the transistor 1258 through the node NC0. The transistor 1270's first end is electrically connected to the bit line RBL-QPB. The transistor 1270's control end is electrically connected to the read-word-line control signal RWLPB. The transistor 1272 has a first end, a second end, and a control end. The transistor 1272's first end is electrically connected to the second end of the transistor 1270. The transistor 1272's second end is electrically connected to the voltage VDD. The transistor 1272's control end is electrically connected to the second end of the transistor 1262, the control end of the transistor 1256, and the control end of the transistor 1258 through the node NC0. In some embodiments of FIG. 12A, the transistors 1254, 1256, 1262, 1266, 1268, 1270 and 1272 are p-type transistors. The transistors 1258, 1260, and 1264 are n-type transistors.

FIG. 12B is a circuit diagram of an N-bit cell 1220 in the 2R1W logic cell array in accordance with some embodiments of the present invention. As shown in FIG. 12B, the N-bit cell 1220 includes a pass transistor 1222, a transistor 1224, a transistor 1226, a transistor 1228, a transistor 1230, a transistor 1232, a transistor 1234, a transistor 1236, a transistor 1238, a transistor 1240, and a transistor 1242. The pass transistor 1222 is electrically connected to the word line WBL and is controlled by a write-word-line control signal WWLP and a write-word-line control signal WWLPB. The transistors 1236 and 1238 charge or discharge or maintain a bit line RBL_QPA according to a read-word-line control signal RWLPA. The transistors 1240 and 1242 charge or discharge or maintain a bit line RBL_QPB according to a read-word-line control signal RWLPB.

The transistor 1232 has a first end, a second end, and a control end. The transistor 1232's first end is electrically connected to the voltage VDD. The transistor 1232's second end is electrically connected to the transistor 1238's control end through a node NC1. The transistor 1232's control end is electrically connected to the pass transistor 1222 through a node b1. The transistor 1234 has a first end, a second end, and a control end. The transistor 1234's first end is electrically connected to the transistor 1238's control end through the node NC1. The transistor 1234's second end is electrically connected to a ground. The transistor 1234's control end is electrically connected to the pass transistor 1122 through the node b1.

The transistor 1224 has a first end, a second end, and a control end. The transistor 1224's first end is electrically connected to the voltage VDD. The transistor 1224's control end is electrically connected to the write-word-line control signal wwl1. The transistor 1226 has a first end, a second end, and a control end. The transistor 1226's first end is electrically connected to the second end of the transistor 1224. The transistor 1226's second end is electrically connected to the pass transistor 1222 through the node b1. The transistor 1226's control end is electrically connected to the transistor 1238's control end through the node NC1. The transistor 1228 has a first end, a second end, and a control end. The transistor 1228's first end is electrically connected to the pass transistor 1222 through the node b1. The transistor 1228's control end is electrically connected to the transistor 1238's control end through the node NC1. The transistor 1230 has a first end, a second end, and a control end. The transistor 1230's first end is electrically connected to the second end of the transistor 1228. The transistor 1230's second end is electrically connected to the ground. The transistor 1230's control end is electrically connected to the write-word-line control signal wwlz1.

The transistor 1236's first end is electrically connected to the bit line RBL-QNA. The transistor 1236's control end is electrically connected to the read-word-line control signal RWLNA. The transistor 1238 has a first end, a second end, and a control end. The transistor 1238's first end is electrically connected to the second end of the transistor 1236. The transistor 1238's second end is electrically connected to the ground. The transistor 1238's control end is electrically connected to the second end of the transistor 1232, the control end of the transistor 1226, and the control end of the transistor 1228 through the node NC1. The transistor 1240's first end is electrically connected to the bit line RBL-QNB. The transistor 1240's control end is electrically connected to the read-word-line control signal RWLNB. The transistor 1242 has a first end, a second end, and a control end. The transistor 1242's first end is electrically connected to the second end of the transistor 1240. The transistor 1242's second end is electrically connected to the ground. The transistor 1242's control end is electrically connected to the second end of the transistor 1232, the control end of the transistor 1226, and the control end of the transistor 1228 through the node NC1. In some embodiments of FIG. 12B, the transistors 1224, 1226, and 1232 are p-type transistors. The transistors 1228, 1230, 1232, 1236, 1238, 1249, and 1242 are n-type transistors.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a logic cell array, comprising:
a plurality of N-bit cells; and
a plurality of P-bit cells,
wherein the N-bit cells and the P-bit cells are alternately row-wise to constitute one column of the logic cell array;
wherein the N-bit cells are disposed on even rows of the logic cell array, and the P-bit cells are disposed on odd rows of the logic cell array.

2. The electronic device as claimed in claim 1, wherein each N-bit cell comprises a first n-type metal-oxide-semiconductor field-effect transistor (N-MOSFET) region and a first p-type metal-oxide-semiconductor field-effect transistor (P-MOSFET) region;
wherein each P-bit cell comprises a second N-MOSFET region and a second P-MOSFET region;
wherein a contact poly pitch (CPP) of the first N-MOSFET region is greater than a CPP of the second N-MOSFET region;
wherein a CPP of the first P-MOSFET region is less than a CPP of the second P-MOSFET region.

3. The electronic device as claimed in claim 2, wherein each N-bit cell and its neighboring P-bit cell forms a rectangle in a top view of a layout to maximize area utilization.

4. The electronic device as claimed in claim 1, further comprising:
a first bit line, electrically connected to the N-bit cells in the column of the logic cell array; and
a second bit line, electrically connected to the P-bit cells in the column of the logic cell array.

5. The electronic device as claimed in claim 4, wherein the first bit line is pre-charged to a logic high level at a start of a read operation; the second bit line is pre-discharged to a logic low level at the start of the read operation.

6. The electronic device as claimed in claim 5, wherein the first bit line is discharged from the logic high level to the logic low level during a read-zero operation; and the first bit line stays at the logic high level during a read-one operation.

7. The electronic device as claimed in claim 6, wherein the second bit line stays at the logic low level during the read-zero operation; and the second bit line is charged to the logic high level during the read-one operation.

8. The electronic device as claimed in claim 6, wherein the read-zero operation is performed when the N-bit cells or the P-bit cells are storing zero; and the read-one operation is performed when the N-bit cells or the P-bit cells are storing one.

9. The electronic device as claimed in claim 4, further comprising:
a read sensing circuit, electrically connected to the logic cell array, configured to determine outputs from the even rows of the logic cell array or the odd rows of the logic cell array, and convert logic levels on the first bit line and the second bit line during a read-zero operation or a read-one operation.

10. The electronic device as claimed in claim 4, wherein each N-bit cell comprises:
a pass transistor, electrically connected to a word line and controlled by a first write-word-line control signal and a second write-word-line control signal;
an NMOS stack, configured to charge or discharge or maintain the first bit line according to a read-word-line control signal;
a first transistor, having a first end, a second end, and a control end; wherein its first end is electrically connected to a first voltage, its second end is electrically connected to the NMOS stack, and its control end is electrically connected to the pass transistor;
a second transistor, having a first end, a second end, and a control end; wherein its first end is electrically connected to the NMOS stack, its second end is electrically connected to a ground, and its control end is electrically connected to the pass transistor;
a third transistor, having a first end, a second end, and a control end; wherein its first end is electrically connected to the first voltage, and its control end is electrically connected to the first write-word-line control signal;
a fourth transistor, having a first end, a second end, and a control end; wherein its first end is electrically connected to the second end of the third transistor, its second end is electrically connected to the pass transistor, and its control end is electrically connected to the NMOS stack;
a fifth transistor, having a first end, a second end, and a control end; wherein its first end is electrically connected to the pass transistor, and its control end is electrically connected to the NMOS stack; and
a sixth transistor, having a first end, a second end, and a control end; wherein its first end is electrically connected to the second end of the fifth transistor, its second end is electrically connected to the ground, and its control end is electrically connected to the second write-word-line control signal.

11. The electronic device as claimed in claim 10, wherein the NMOS stack comprises:
a seventh transistor, having a first end, a second end, and a control end; wherein its first end is electrically connected to the first bit line, and its control end is electrically connected to the read-word-line control signal; and
an eighth transistor, having a first end, a second end, and a control end; wherein its first end is electrically connected to the second end of the seventh transistor, its second end is electrically connected to the ground, and its control end is electrically connected to the second end of the first transistor, the control end of the fourth transistor, and the control end of the fifth transistor.

12. The electronic device as claimed in claim 4, wherein each P-bit cell comprises:
a pass transistor, electrically connected to a word line and controlled by a first write-word-line control signal and a second write-word-line control signal;
a PMOS stack, configured to charge or discharge or maintain the second bit line according to a read-word-line control signal;
a first transistor, having a first end, a second end, and a control end; wherein its first end is electrically connected to a first voltage, its second end is electrically connected to the PMOS stack, and its control end is electrically connected to the pass transistor;
a second transistor, having a first end, a second end, and a control end; wherein its first end is electrically connected to the PMOS stack, its second end is electrically connected to a ground, and its control end is electrically connected to the pass transistor;
a third transistor, having a first end, a second end, and a control end; wherein its first end is electrically connected to the first voltage, and its control end is electrically connected to the first write-word-line control signal;
a fourth transistor, having a first end, a second end, and a control end; wherein its first end is electrically connected to the second end of the third transistor, its second end is electrically connected to the pass transistor, and its control end is electrically connected to the PMOS stack;
a fifth transistor, having a first end, a second end, and a control end; wherein its first end is electrically connected to the pass transistor, and its control end is electrically connected to the PMOS stack; and
a sixth transistor, having a first end, a second end, and a control end; wherein its first end is electrically connected to the second end of the fifth transistor, its second end is electrically connected to the ground, and its control end is electrically connected to the second write-word-line control signal.

13. The electronic device as claimed in claim 12, wherein the PMOS stack comprises:
a seventh transistor, having a first end, a second end, and a control end; wherein its first end is electrically connected to the second bit line, and its control end is electrically connected to the read-word-line control signal; and
an eighth transistor, having a first end, a second end, and a control end; wherein its first end is electrically connected to the second end of the seventh transistor, its second end is electrically connected to the first voltage, and its control end is electrically connected to the second end of the first transistor, the control end of the fourth transistor, and the control end of the fifth transistor.

14. The electronic device as claimed in claim 9, wherein the read sensing circuit comprises:
a local input and output (IO) circuit, electrically connected to the logic cell array, configured to convert logic levels on the first bit line based on a first pre-charge signal and convert the logic levels on the second bit line based on a second pre-charge signal during the read-zero operation or the read-one operation;
a global IO circuit, electrically connected to the local IO circuit, configured to determine outputs from the even rows of the logic cell array or the odd rows of the logic cell array based on a first selection signal and a second selection signal.

15. The electronic device as claimed in claim 14, wherein the local IO circuit outputs a first global signal to the global IO circuit based on the logic levels on the first bit line, and outputs a second global signal to the global IO circuit based on the logic levels on the second bit line.

16. The electronic device as claimed in claim 15, wherein the global IO circuit outputs a read-result signal based on the first and second selection signals, the first global signal, the second global signal, and data stored in the N-bit cells and the P-bit cells.

17. The electronic device as claimed in claim 14, wherein the local IO circuit comprises:
a first transistor, having a first end, a second end, and a control end; wherein its first end is electrically connected to a first voltage, its second end is electrically connected to the first bit line, and its control end is electrically connected to the first pre-charge signal;
a second transistor, having a first end, a second end, and a control end; wherein its first end is electrically connected to the second bit line, its second end is electrically connected to a ground, and its control end is electrically connected to the second pre-charge signal.

18. The electronic device as claimed in claim 15, further comprising:
a second logic cell array, comprising:
a plurality of N-bit cells; and
a plurality of P-bit cells,
wherein the N-bit cells and the P-bit cells are alternately row-wise to constitute one column of the logic cell array;
wherein the N-bit cells are disposed on even rows of the logic cell array, and the P-bit cells are disposed on odd rows of the logic cell array.

19. The electronic device as claimed in claim 18, wherein the local IO circuit is electrically connected between the logic cell array and the second logic cell array.

20. The electronic device as claimed in claim 19, further comprising:
a third bit line, electrically connected to the N-bit cells in the column of the second logic cell array; and
a fourth bit line, electrically connected to the P-bit cells in the column of the second logic cell array.

21. The electronic device as claimed in claim 20, wherein the local IO circuit further comprises:
a NAND gate, electrically connected to the first bit line and the third bit line, and configured to perform a NAND operation on the logic levels of the first bit line and the third bit line to obtain a first result;
a NOR gate, electrically connected to the second bit line and the fourth bit line, and configured to perform a NOR operation on the logic levels of the second bit line and the fourth bit line to obtain a second result;
a first inverter, electrically connected to the NAND gate, and configured to invert the first result to output the first global signal; and
a second inverter, electrically connected to the NOR gate, and configured to invert the second result to output the second global signal.
